(19) United States
(12) Patent Application Publication
(10) Pub. No.: US 2010/0307417 A1
(43) Pub. Date: Dec. 9, 2010

(54) Manufacturing device for silicon carbide single crystal

(75) Inventors: Jun Kojima, Iwakura-city (JP); Yasuo Kitou, Okazaki-city (JP); Sonia De Angelis, Milan (IT); Ambrogio Peccenati, Castiglione d'Adda (IT); Giuseppe Tarenzi, Castiglione d'Adda (IT)

Correspondence Address: POSZ LAW GROUP, PLC, 12040 SOUTH LAKES DRIVE, SUITE 101, RESTON, VA, 20191, US

(73) Assignees: DENSO CORPORATION, Kariya-city (JP); LPE S.p.A., Milan (IT)

(21) Appl. No.: 12/801,225

(22) Filed: May 27, 2010

(30) Foreign Application Priority Data
Jun. 3, 2009 (JP) 2009-133910

(51) Int. Cl. C23C 16/32

(52) U.S. Cl. 118/724

(57) ABSTRACT

A manufacturing device of a silicon carbide single crystal includes: a reaction chamber; a seed crystal arranged in the reaction chamber; and a heating chamber. The seed crystal is disposed on an upper side of the reaction chamber, and the gas is supplied from an under side of the reaction chamber. The heating chamber is disposed on an upstream side of a flowing passage of the gas from the reaction chamber. The heating chamber includes a hollow cylindrical member, a raw material gas inlet, a raw material gas supply nozzle and multiple baffle plates. The inlet introduces the gas into the hollow cylindrical member. The nozzle discharges the gas from the hollow cylindrical member to the reaction chamber. The baffle plates are arranged on the flowing passage of the gas between the inlet and the nozzle.

### CROSS REFERENCE TO RELATED APPLICATION

This application is based on Japanese Patent Application No. 2009-133910 filed on Jun. 3, 2009, the disclosure of which is incorporated herein by reference.

### FIELD OF THE INVENTION

The present invention relates to a manufacturing device for a silicon carbide (i.e., SiC) single crystal.

### BACKGROUND OF THE INVENTION

Conventionally, in a manufacturing process of a SiC single crystal, when a particle is mixed in the SIC single crystal, a problem occurs such that crystal defects such as a dislocation, a micro pile and a polymorphism is generated from the particle as an origin of the defects. This is because the particle floats and flows from an upstream side when a raw material gas is introduced, the particle is attached to a growth surface during the crystal growth, and then, the particle is retrieved into the growth crystal. Accordingly, it is desired to provide a manufacturing device with reducing to mix the particle into the SiC single crystal.

A manufacturing device having a structure described in, for example, Patent Document No. 1 is presented as a manufacturing device for the SiC single crystal to reduce to mix the particle. Specifically, a mixed gas from an introduction pile blows on a baffle plate so that the gas flow changes the direction in a heater chamber, and then, the gas is introduced to the SiC single crystal substrate as a seed crystal.

[Patent Document No. 1]

Japanese Patent Application Publication No. 2003-137695

However, in the structure described in the Patent Document No. 1, although the gas does not directly blow on the SiC single crystal substrate because of the baffle plate, the baffle plate does not remove the particle completely. Thus, the particle rides on the gas flow and reaches the SiC single crystal substrate. Accordingly, it is required to provide a manufacturing device for preventing the particle from reaching the SiC single crystal substrate.

### SUMMARY OF THE INVENTION

In view of the above-described problem, it is an object of the present disclosure to provide a manufacturing device of a SiC single crystal for preventing a particle from reaching a SiC single crystal substrate so that a SiC single crystal with high quality is manufactured.

According to a first aspect of the present disclosure, a manufacturing device of a silicon carbide single crystal includes: a reaction chamber; a seed crystal made of a silicon carbide single crystal substrate and arranged in the reaction chamber; and a heating chamber for heating a raw material gas. The seed crystal is disposed on an upper side of the reaction chamber. The raw material gas is supplied from an under side of the reaction chamber so that the gas reaches the seed crystal, and the silicon carbide single crystal is grown on the seed crystal. The heating chamber is disposed on an upstream side of a flowing passage of the raw material gas from the reaction chamber. The heating chamber includes a hollow cylindrical member, a raw material gas inlet, a raw material gas supply nozzle and a plurality of baffle plates. The raw material gas inlet introduces the raw material gas into the hollow cylindrical member.

The raw material gas supply nozzle discharges the raw material gas from the hollow cylindrical member to the reaction chamber. The plurality of baffle plates are arranged on the flowing passage of the raw material gas between the raw material gas inlet and the raw material gas supply nozzle.

Thus, the plurality of baffle plates are arranged on the flowing passage of the raw material gas between the raw material gas inlet and the raw material gas supply nozzle. Accordingly, the raw material gas including a particle collides on the plurality of baffle plates, which are arranged on the flowing passage of the raw material gas between the raw material gas inlet and the raw material gas supply nozzle. The flowing direction of the raw material gas is changed many times so that the gas flows in a flowing passage length, which is longer than a case where the baffle plate is not arranged and a case where one baffle plate is arranged in one stage manner. Accordingly, a time interval, in which the raw material gas is exposed in high temperature circumstance in the heated heating chamber 9, is lengthened. Accordingly, the particle is decomposed, and the particle does not reach a surface of the seed crystal and a growing surface of the SiC single crystal. Thus, the device manufactures the SiC single crystal with high quality.

According to a second aspect of the present disclosure, a manufacturing device of a silicon carbide single crystal includes: a reaction chamber; a seed crystal made of a silicon carbide single crystal substrate and arranged in the reaction chamber; and a heating chamber for heating a raw material gas. The seed crystal is disposed on an upper side of the reaction chamber. The raw material gas is supplied from an under side of the reaction chamber so that the gas reaches the seed crystal, and the silicon carbide single crystal is grown on the seed crystal. The heating chamber is disposed on an upstream side of a flowing passage of the raw material gas from the reaction chamber. The heating chamber includes a hollow cylindrical member, a raw material gas inlet, a raw material gas supply nozzle and a spiral passage portion. The raw material gas inlet introduces the raw material gas into the hollow cylindrical member. The raw material gas supply nozzle discharges the raw material gas from the hollow cylindrical member to the reaction chamber. The spiral passage portion provides a spiral flowing passage of the raw material gas between the raw material gas inlet and the raw material gas supply nozzle.

Thus, since the spiral passage portion is formed in the heating chamber so that the spiral shaped flowing passage is provided, the flowing passage of the raw material gas is elongated. In this case, a time interval, in which the raw material gas is exposed in high temperature circumstance in the heated heating chamber, is much lengthened. Thus, the device manufactures the SiC single crystal with high quality.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a manufacturing device of a SiC single crystal according to a first embodiment of the present disclosure;

FIGS. 2A and 2B are image views of a′ heating chamber of the manufacturing device of the SiC single crystal shown in FIG. 1, FIG. 2A is a cross sectional image view, and FIG. 2B is a perspective image view;

FIGS. 3A and 3B are image views showing a heating chamber of a manufacturing device of the SiC single crystal according to a second embodiment of the present disclosure, FIG. 3A is a cross sectional image view, and FIG. 3B is a perspective view;

FIG. 4 is a cross sectional image view showing a heating chamber in a manufacturing device of the SiC single crystal according to a third, embodiment of the present disclosure;

FIG. 5A is a perspective image view showing a baffle plate, and FIG. 5B is a cross sectional image view showing the baffle plate taken along a direction perpendicular to a center axis of a hollow cylindrical member;

FIG. 6 is a cross sectional image view showing a baffle plate in a heating chamber of the manufacturing device of SiC single crystal according to a fourth embodiment of the present disclosure taken along a direction perpendicular to the center axis of the hollow cylindrical member;

FIGS. 7A to 7C are image views showing a heating chamber in a manufacturing device of SiC single crystal according to a fifth embodiment of the present disclosure, FIG. 7A is a cross sectional image view showing the heating chamber, FIG. 7B is a perspective image view showing one baffle plate of the heating chamber retrieved from the chamber, and FIG. 7C is a partial enlarged cross sectional image view showing the baffle plate;

FIGS. 8A and 8B are image views showing a heating chamber in a manufacturing device of SiC single crystal according to a sixth embodiment of the present disclosure, FIG. 8A is a cross sectional image view showing the heating chamber, and FIG. 8B is a perspective image view showing a baffle plate;

FIGS. 9A and 9B are image views showing a heating chamber in a manufacturing device of SiC single crystal according to a seventh embodiment of the present disclosure, FIG. 9A is a cross sectional image view showing a heating chamber, and FIG. 9B is a perspective image view showing a baffle plate;

FIG. 10 is a partially enlarged cross sectional image view showing a baffle plate of a heating chamber in a manufacturing device of SiC single crystal according to an eighth embodiment of the present disclosure;

FIGS. 11A and 11B are image views showing a heating chamber in a manufacturing device of SiC single crystal according to a ninth embodiment of the present disclosure, FIG. 11A is a cross sectional image view of the heating chamber, and FIG. 11B is a perspective image view of the baffle plate;

FIGS. 12A and 12B are image views showing a heating chamber in a manufacturing device of SiC single crystal according to a tenth embodiment of the present disclosure, FIG. 12A is a cross sectional image view showing a heating chamber, and FIG. 12B is a partially enlarged cross sectional image view showing a baffle plate;

FIGS. 13A and 13B are image views showing a heating chamber in a manufacturing device of SiC single crystal according to an eleventh embodiment of the present disclosure, FIG. 13A is a cross sectional image view showing a heating chamber, and FIG. 13B is a perspective image view showing the heating chamber;

FIG. 14 is a perspective image view showing a heating chamber in a manufacturing device of SiC single crystal according to a twelfth embodiment of the present disclosure;

FIG. 15 is a perspective image view showing a heating chamber in a manufacturing device of SiC single crystal according to a thirteenth embodiment of the present disclosure;

FIG. 16A is a cross sectional view showing a center portion of the flowing passage of the raw material gas in the heating chamber in FIG. 15 taken along a center axis direction of the hollow cylindrical member, and FIG. 16B is a front view showing one baffle plate;

FIG. 17 is a cross sectional view showing a center portion of the flowing passage of the raw material gas in a heating chamber of a manufacturing device of SiC single crystal according to a fourteenth embodiment of the present disclosure taken along a center axis direction of the hollow cylindrical member;

FIG. 18 is a cross sectional view showing a center portion of the flowing passage of the raw material gas in a heating chamber of a manufacturing device of SiC single crystal according to a fifteenth embodiment of the present disclosure taken along a center axis direction of the hollow cylindrical member;

FIGS. 19A and 19B are image views showing a heating chamber in a manufacturing device of SiC single crystal according to a sixteenth embodiment of the present disclosure, FIG. 19A is a perspective image view showing a heating chamber, and FIG. 19B is a cross sectional view showing a center portion of the flowing passage of the raw material gas in the heating chamber taken along a center axis direction of the hollow cylindrical member;

FIG. 20 is a cross sectional view showing a center portion of the flowing passage of the raw material gas in a heating chamber of a manufacturing device of SiC single crystal according to a seventeenth embodiment of the present disclosure taken along a center axis direction of the hollow cylindrical member;

FIG. 21 is a cross sectional view showing a center portion of the flowing passage of the raw material gas in a heating chamber of a manufacturing device of SiC single crystal according to a eighteenth embodiment of the present disclosure taken along a center axis direction of the hollow cylindrical member;

FIG. 22 is a cross sectional view showing a center portion of the flowing passage of the raw material gas in a heating chamber of a manufacturing device of SiC single crystal according to a nineteenth embodiment of the present disclosure taken along a center axis direction of the hollow cylindrical member;

FIG. 23 is a perspective image view showing a heating chamber in a manufacturing device of SiC single crystal according to a twentieth embodiment of the present disclosure;

FIGS. 24A to 24F are schematic views showing example patterns of an opening formed in a baffle plate;

FIGS. 25A to 25E are schematic views showing example patterns of an opening formed in a baffle plate; and

FIGS. 26A to 26C are perspective image views showing examples of a structure of a rectifier system.

### DETAILED DESCRIPTION OF THE PREFERRED EMBODIMENTS

### First Embodiment

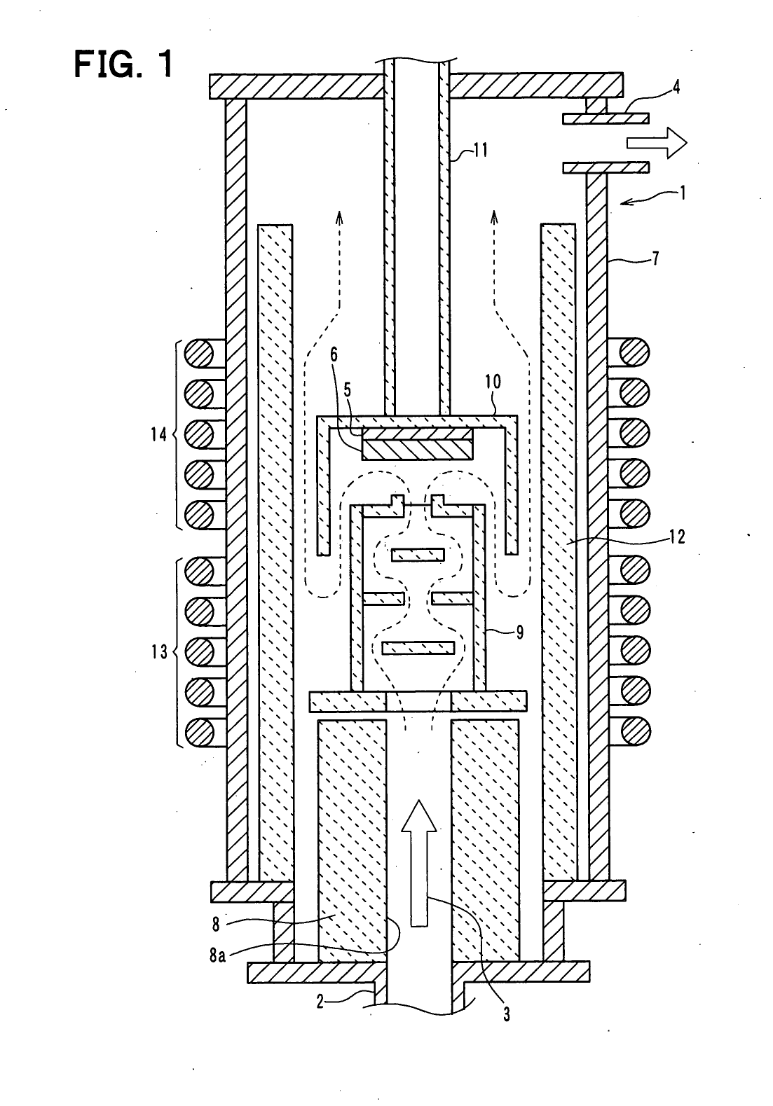

FIG. 1 is a cross sectional view showing a manufacturing device of SIC single crystal according to the present embodiment. The structure of the manufacturing device of the SIC single crystal will be explained with reference to the drawing.

The manufacturing device 1 of SIC single crystal shown in FIG. 1 supplies a raw material gas 3 of SiC including silicon and carbon through an inlet 2, which is disposed on a bottom, and discharges the gas through an outlet 4 disposed on au upper side so that the device performs crystal growth of SIC single crystal 6 on a seed crystal 5 formed from a SIC single crystal substrate, which is mounted in the manufacturing device 1 of SIC single crystal.

The manufacturing device 1 of SiC single crystal includes a vacuum chamber 7, a first heat insulator 8, a heating chamber r9, a reaction chamber 10, a pipe 11, a second heat insulator 12 and first and second heating elements 13, 14.

The vacuum chamber 7 has a hollow cylindrical shape. Argon gas is introduced into the vacuum chamber 7. Further, the vacuum chamber 7 accommodates other elements in the manufacturing device 1 of SiC single crystal. The pressure in an inner space in the vacuum chamber 7 is vacuumed so that the pressure is reduced. The inlet 2 of the raw material gas 3 is formed on the bottom of the vacuum chamber 7. Further, an outlet 4 of the raw material gas 3 is formed on an upper side (specifically, on an upper position of an sidewall).

The first heat insulator 8 has a cylindrical shape such as a cylinder. A hollow portion of the insulator 8 provides a raw material gas introduction pile 8a. The first heat insulator 8 is made of, for example, graphite or graphite with a TaC (tantalum carbide) coated surface.

The heating chamber 9 is arranged on an upstream side of a flowing passage of the raw material gas 3 from the reaction chamber 10. The heating chamber 9 functions as a mechanism for eliminating a particle included in the raw material gas 3 while the raw material gas 3 supplied from the inlet 2 is introduced to the seed crystal 5. The heating chamber 9 provides a feature of the present disclosure. The detail of the feature will be explained later.

The reaction chamber 10 provides a space in which the raw material gas 3 flows. The reaction chamber 10 has a cylindrical shape with a bottom. In the present embodiment, the reaction chamber 10 has the cylindrical shape with the bottom. The reaction chamber 10 is made of, for example, graphite or graphite with a TaC (tantalum carbide) coated surface. One end of the heating chamber 9 is inserted into the opening of reaction chamber 10. A space as a reaction space is formed between the one end of the heating chamber 9 and the bottom of the reaction chamber 10. The SiC single crystal 6 is grown on the seed crystal 5, which is mounted on the bottom of the reaction chamber 10.

One end of the pipe 11 is connected to a portion of the bottom of the reaction chamber 10, which is opposite to the heating chamber 9. The other end of the pipe 11 is connected to a rotation pull-up mechanism (not shown). This mechanism provides to rotate and to pull up the pipe 11 together with the reaction chamber 10, the seed crystal 5 and the SiC single crystal 6. The mechanism provides to restrict formation of temperature distribution on a growing surface of the SiC single crystal 6. Further, the mechanism controls temperature of the growing surface to be an appropriate temperature for the growth according to the growth of the SiC single crystal 6. The pipe 11 is also made of graphite or graphite with a TaC (tantalum carbide) coated surface.

The second heat insulator 12 is arranged along with a sidewall of the vacuum chamber 7. The insulator 12 has a hollow cylindrical shape. The second heat insulator 12 substantially surrounds the first heat insulator 8, the heating chamber 9, the reaction, chamber 10 and the like. The second heat insulator 12 is made of, for example, graphite or graphite with a TaC (tantalum carbide) coated surface.

The first and second heating elements 13, 14 are formed from an induction heating coil or a heater, for example. The first and second heating elements 13, 14 surround the vacuum chamber 7. The first and second heating elements 13, 14 independently control temperature. Thus, they can perform temperature control precisely. The first heating element 13 is disposed at a position corresponding to a top position on an opening side of the reaction chamber 10 and the heating chamber 9. The second heating element 14 is disposed at a position corresponding to the reaction space provided by the reaction chamber 10. Thus, since they have such arrangement, the temperature distribution of the reaction space is controlled to be appropriate for the growth of the SiC single crystal 6. Further, the temperature of the heating chamber 9 is controlled to be appropriate temperature for eliminating the particle.

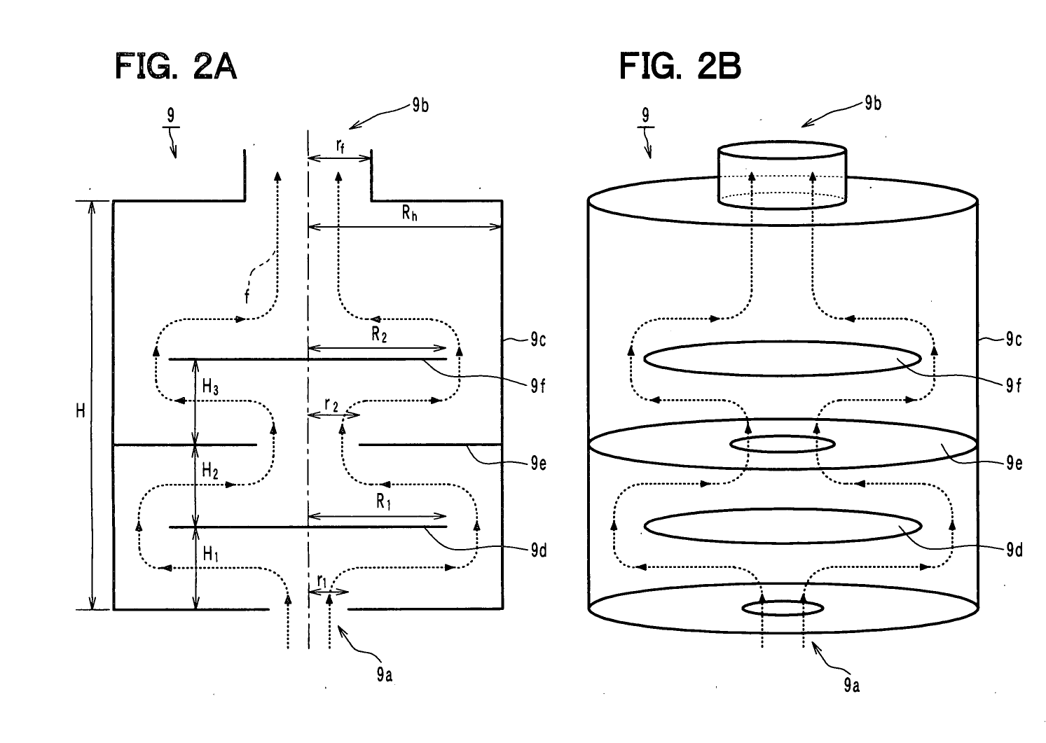

Next, the detailed structure of the heating chamber 9 of the manufacturing device of SiC single crystal will be explained. FIGS. 2A and 2B are image views showing the heating chamber 9 of the manufacturing device of SiC single Crystal shown in FIG. 1, FIG. 2A is a cross sectional image view, and FIG. 2B is a perspective image view.

As shown in FIGS. 2A and 2B, the heating chamber 9 includes a hollow cylindrical member 9c, in which a raw material gas inlet 9a and a raw material gas supply nozzle 9c are formed, and multiple baffle plates 9d-9f arranged in the hollow cylindrical member 9c along with a center axis as an arrangement direction in a multiple stage manner that each plate 9d-9f intersects with a center axis of the hollow cylindrical member 9c. Specifically, in the present embodiment, the chamber 9 includes multiple baffle plates 9d-9f, which is perpendicular to the center axis of the hollow cylindrical member 9c.

The raw material gas inlet 9a is disposed on a center of the bottom of the hollow cylindrical member 9c. The raw material gas inlet 9a is connected to the raw material gas introduction pipe 8a, which is formed in the first heat insulator 8. Thus, the inlet 9a provides an entrance, through which the raw material gas 3 is introduced. The raw material gas supply nozzle 9b is disposed on the center of the upper portion of the hollow cylindrical member 9c. The raw material gas supply nozzle 9b provides a supply port, from which the raw material gas 3 passing through the hollow cylindrical member 9c is introduced to the growing surface of the SiC single crystal 6 or the seed crystal 5. The raw material gas supply nozzle 9b may merely open the upper portion of the hollow cylindrical member 9c. The nozzle 9b protrudes toward the reaction chamber 10 side so that a supply direction of the raw material gas 3 is perpendicular to the growing surface of the SiC single crystal 6.

The hollow cylindrical member 9c has a tube shape. In the present embodiment, the member 9c has a cylindrical shape. A radius Rh of the hollow cylindrical member 9c may be any value. For example, the radius Rh may be in a range between 50 millimeters and 60 millimeters.

Multiple baffle plates 9d-9f have a surface, which intersects with a flowing direction of the raw material gas 3. The plates 9d-9f blocks displacement of the raw material gas 3. Further, the flowing passage of the raw material gas 3 in the heating chamber 9 is elongated to be longer than a direct distance between the raw material gas inlet 9c and the raw material gas supply nozzle 9b. Specifically, when an average flowing passage length f is defined as a passage flowing through a center of a flowing passage of the raw material gas 3 in the heating chamber 9, the average flowing passage length f and a direct distance H between the raw material gas inlet 9c and the raw material gas supply nozzle 9b has a relationship of f>1.2H. The number of multiple baffle plates 9d-9f may be any. In the present embodiment, the number is three. A distance H1 between the hollow cylindrical member 9c and the baffle plate 9d, distances H2, H3 among baffle plates 9d-9f may be any. For example, the distance H1 is 15 millimeters, the distance H2 is 20 millimeters, and the distance H3 is 30 millimeters.

A utmost under baffle plate 9d disposed nearest the raw material gas inlet 9a side has a circular shape. The radius R1 of the plate 9d is larger than a radius r1 of the raw material gas inlet 9a. The dimension of the radius R1 is set to cover a whole of the raw material gas inlet 9a seeing from an upper side of the heating chamber 9. For example, the radius R1 is in a range between 20 millimeters and 40 millimeters. The baffle plate 9d changes the flowing direction of the raw material gas 3 introduced from the raw material gas inlet 9a to a vertical direction so that the raw material gas 3 is introduced to a side wall side of the hollow cylindrical member 9c. Further, the gas 3 is introduced to an upper side along with the side wall of the member 9c. The baffle plate 9d has a structure without forming an opening at a center of the plate 9d since the raw material gas 3 surely and effectively collides on the plate 9d.

A middle baffle plate 9e disposed on the raw material gas inlet 9a side next to the baffle plate 9d has a ring shape with a circular opening at a center of the plate 9e. A radius r2 of the opening formed at the center of the baffle plate 9e is smaller than the radius R1 of the baffle plate 9d. The baffle plate 9e changes the flowing direction of the raw material gas 3 introduced to the upper side along with the side wall of the hollow cylindrical member 9c toward the center axis of the hollow cylindrical member 9c, and then, the flowing direction is changed at the center of the plate 9e to the upper side. Thus, the gas 3 passes through the opening of the baffle plate 9e.

An utmost upper baffle plate 9f disposed on the raw material gas inlet 9a side next to the baffle plate 9e has a circular shape. A radius R2 of the plate 9f is larger than the radius r2 of the opening of the baffle plate 9e. The dimension of the radius R2 is set to cover the opening of the baffle plate 98e seeing from the upper side of the heating chamber 9 and to cover a whole of the raw material gas nozzle 9b seeing from the under side of the heating chamber 9. For example, the radius R2 is in a range between 20 millimeters and 40 millimeters. The baffle plate 9f changes the flowing direction of the raw material gas 3 passing through the opening of the baffle plate 9e to the vertical direction so that the plate 9f introduces the raw material gas 3 to the sidewall of the hollow cylindrical member 9c. Further, the gas is introduced to the upper side along with the side wall. The baffle plate 9f is the nearest to the raw material gas supply nozzle 9b. The baffle plate 9f has a structure without forming an opening at a center of the plate 9f since the raw material gas 3 surely and effectively collides on the upper side of the hollow cylindrical member 9c before the gas reaches the raw material gas supply nozzle 9b.

Thus, the raw material gas 3 collides on each baffle plate 9d-9f arranged in a multiple stage manner so that the flowing direction of the gas 3 is changed. Since the radius rf of the raw material gas supply nozzle 9b is smaller than the radius R2, the raw material gas 3 finally collides on the upper side of the hollow cylindrical member 9c. Then, the gas 3 is discharged from the raw material gas supply nozzle 9b, and supplied to the reaction chamber. Here, although a case where only one middle baffle plate 9e is arranged between the utmost under baffle plate 9d and the utmost upper baffle plate 9f is explained, the number of the middle baffle plate 9e may be larger than one. In this case, one of the middle baffle plates 9e adjacent to the utmost under baffle-plate 9d may havea ring shape, and another one of the middle baffle plates 9e disposed on the one of the middle baffle plates 9e may have a circular shape. Thus, the one plate 9e having the ring shape and the other plate 9e having the circular shape are alternately repeated. Then, the utmost upper baffle plate 9f has the circular shape. In this case, since the radius of the baffle plate 9e having the circular shape is larger than the radius of the opening of the baffle plate 9e having the ring shape disposed under the baffle plate 9e having the circular shape, the raw material gas 3 collides on each baffle plate surely so that the flowing passage is changed.

Since the baffle plates 9d-9f are arranged in the multiple stage manner, the flowing passage length of the raw material gas 3 is elongated, compared with a case where the chamber 9 has no baffle plate 9d-9f or a case where the chamber 9 has one baffle plate in one stage manner. Accordingly, a time interval, in which the raw material gas 3 is exposed in high temperature circumstance in the heated heating chamber 9, is lengthened. Here, to explain simply, the baffle plates 9d, 9f are shown in an image view in which they are floated in the hollow cylindrical member 9c. However, although not shown in the drawings, the baffle plates 9d, 9f may be supported with a support member, which extends from a sidewall of the hollow cylindrical member 9c or is connected to the upper side or the bottom of the hollow cylindrical member 9c or the baffle plate 9e.

Thus, a manufacturing method of the SiC single crystal 6 with using the manufacturing device of the SiC single crystal having the above construction will be explained.

First, the first and second heating elements 13, 14 are controlled so that a predetermined temperature distribution is obtained. Specifically, the predetermined temperature provides to re-crystallize the raw material gas 3 on the surface of the seed crystal 5 in order to grow the SiC single crystal 6, and further provides to increase a sublimation rate higher than a re-crystallization rate in the heating chamber 9.

The vacuum chamber 7 is controlled to be a predetermined pressure. If necessary, argon gas is introduced into the chamber 7. Thus; the raw material gas 3 is introduced into the chamber 7 through the raw material gas introduction pipe 8a. Thus, as shown with a broken line arrow in FIGS. 1 and 2(a) and 2(b), the raw material gas 3 flows so that the gas is supplied to the seed crystal 5, and the SiC single crystal 6 is grown.

At this time, the raw material gas 3 may include a particle. The particle is formed, for example, from aggregation of silicon components or carbon components in the raw material gas 3, from scrapping of a part made of graphite on an inner wall of the gas passage, or from scrapping of SiC attached to the inner wall of the gas passage. The particle is disposed in the raw material gas 3 so that the particle flows.

However, the raw material gas 3 including the particle collides on multiple baffle plates 9d-9f arranged in the multiple stage manner so that the flowing direction is changed multiple times. Thus, the gas 3 is displaced in the long flowing passage length, compared with a case where the heating chamber 9 includes no baffle plate 9d-9f or a case where the chamber 9 includes one stage baffle plate 9d-9f. Accordingly, the time interval, in which the raw material gas 3 is exposed in high temperature circumstance in the heated heating chamber 9, is lengthened. Accordingly, the particle is decomposed, and the particle does not reach a surface of the seed crystal 5 and a growing surface of the SiC single crystal 6. Thus, the device manufactures the SiC single crystal with high quality.

Further, when the number of baffle plates becomes large so that the number of times of changes of the flowing direction is large, a possibility for colliding the particle on multiple baffle plates 9d-9f and the hollow cylindrical member 9c increases. Thus, the particle can capture in the heating chamber 9. Accordingly, the particle does not reach the surface of the seed crystal 5 and the growing surface of the SiC single crystal 6. Specifically, the flowing speed of the gas 3 increases at the raw material gas inlet 9a, and the flowing speed of the gas 3 is reduced gradually toward the raw material gas supply nozzle 9b. Thus, the particle is captured effectively. Accordingly, the distances H1, H2, H3 are set to be, for example, 15 millimeters, 20 millimeters and 30 millimeters, respectively. Thus, the relationship among the distances H1, H2, H3 is H1>=H2>=H3. Thus, the above effect is obtained effectively.

The particle having a grain diameter equal to or smaller than 3 millimeters is observed to attach to the baffle plates 9d-9f when the SiC single crystal 6 is manufactured by the above manufacturing method. Since a kinetic energy of the particle is larger than a component of the raw material gas 3, which is completely gasified, the particle fails to curve when the flowing direction is changed. Thus, the particle collides on the baffle plates 9d-9f, and then, is attached to the plates 9d-9f. According to the observation result, the particle is restricted from reaching the surface of the seed crystal 5 and the growing surface of the SiC single crystal 6.

### Second Embodiment

A second embodiment of the present disclosure will be explained. In the present embodiment, an additional baffle plate is formed, compared with the first embodiment. Other features are similar to the first embodiment. Thus, only different parts will be explained.

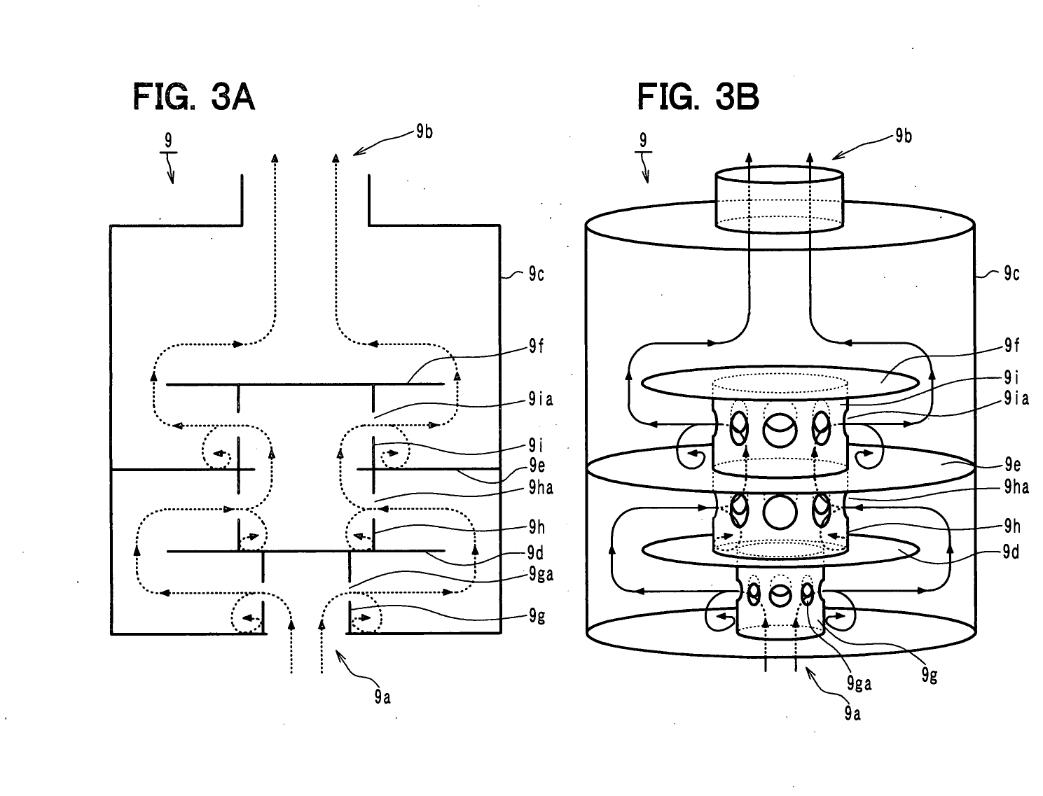

FIGS. 3A and 3B are image views of the heating chamber 9 accommodated in the manufacturing device of the SiC single crystal according to the present embodiment. FIG. 3A is a cross sectional image view, and FIG. 3B is a perspective image view. Other parts of the manufacturing device of the SiC single crystal are similar to those in FIG. 1 according to the first embodiment.

As shown in FIGS. 3A and 3B, the heating chamber 9 further includes baffle plates (as sub baffle plates) 9g, 9h, 9i in addition to the baffle plates 9d-9f, which are arranged along the vertical direction with respect to the center axis of the hollow cylindrical member 9c. The sub baffle plates 9g, 9h, 9i intersect with the baffle plates 9d-9f, and further, extend along with a direction crossing a radial direction with respect to the center axis of the hollow cylindrical member 9c. Specifically, in the present embodiment, the baffle plates 9g, 9h, 9i are in parallel to the center axis of the hollow cylindrical member 9c.

Each baffle plate 9g-9i is formed from a cylindrical member having multiple openings 9ga, 9ha, 9ia. The baffle plate 9g is arranged to connect between the bottom of the hollow cylindrical member 9c and the baffle plate 9d. Further, the baffle plate 9g supports the baffle plate 9d. The baffle plate 9h is arranged to connect between the baffle plate 9d and the baffle plate 9e. The baffle plate 9i is arranged to connect between the baffle plate 9e and the baffle plate 9f. Further, the baffle plate 9i supports the baffle plate 9f. A diameter of the baffle plate 9g is larger than the raw material gas inlet 9a. The diameter of each of the baffle plates 9h, 9i is larger than the diameter of the opening formed in the baffle plate 9e.

Multiple openings 9ga, 9ha, 9ia formed in each baffle plate 9g-9i are eight openings in the present embodiment. The openings 9ga, 9ha, 9ia are arranged at equal intervals around the center axis of the hollow cylindrical member 9c. The openings 9ga, 9ha, 9ia may have various shape. In the present embodiment, each opening 9ga, 9ha, 9ia has a circular shape with a diameter φ in a range between 10 millimeters and 30 millimeters.

In the manufacturing device of the SiC single crystal having the above features, the raw material gas 3 flows through multiple openings 9ga, 9ha, 9ia. At this time, when the raw material gas 3 passes through the baffle plates 9g-9i the flowing speed increases since the flowing passage is narrowed. Thus, the particle easily collides on the baffle plates 9g-9i. Further, as shown with an arrow in the drawings, a vortex is generated in the gas flow on the down stream side of the flowing direction of the raw material gas 3 with respect to each baffle plate 9g-9i. The particle is captured in the vortex. Thus, the particle is accumulated at a under portion on the down stream side of the flowing direction. Thus, the time interval, in which the raw material gas 3 is exposed in high temperature circumstance, is much lengthened. Accordingly, the particle is effectively decomposed and disappeared. Further, the decomposed particle may be merged into the raw material gas 3 again so that the particle provides growing material. Even if the particle is persistent, the particle is continuously captured in the vortex. Thus, the particle is prevented from being attached to the growing surface of the SiC single crystal 6, and therefore, the device manufactures the SiC single crystal 6 with high quality.

### Third Embodiment

A third embodiment of the present disclosure will be explained. In the present embodiment, each baffle plate 9g-9i explained in the second embodiment includes multiple plates. Other features are similar to the second embodiment. Thus, only different parts will be explained.

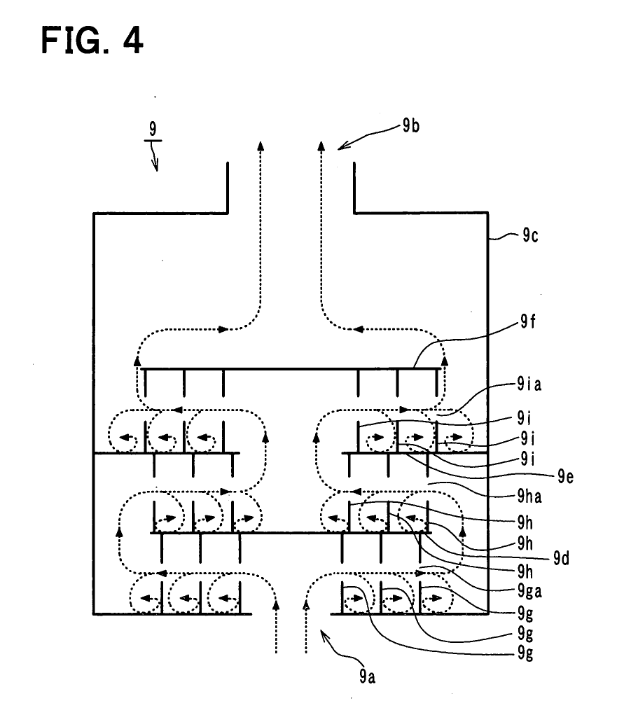

FIG. 4 is a cross sectional image view of the heating chamber 9 accommodated in the manufacturing device of the SiC single crystal according to the present embodiment. Other parts of the manufacturing device of the SiC single crystal are similar to those in FIG. 1 according to the first embodiment.

As shown in FIG. 4, in the heating chamber 9, each baffle plates 9g-9i includes multiple plates, which is in parallel to the center axis of the hollow cylindrical member 9c. In the present embodiment, the number of the plates is three. Each baffle plate 9g-9i is arranged concentrically around a center of the center axis of the hollow cylindrical member 9c. A distance between two adjacent baffle plates 9g-9i may be any. For example, the distance may be 10 millimeters.

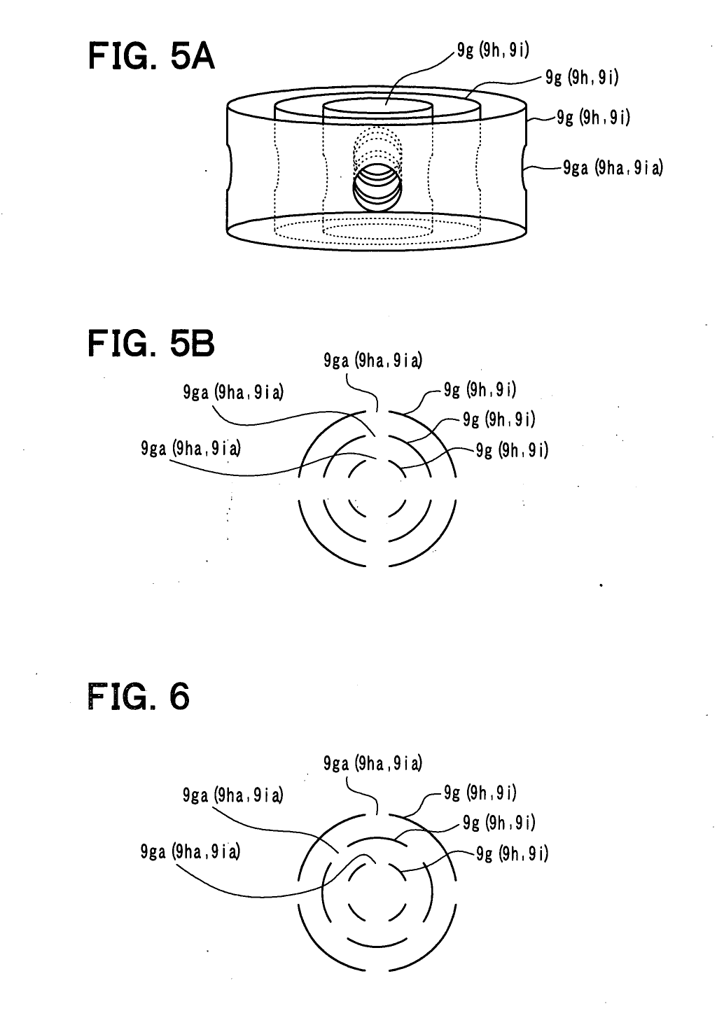

FIG. 5A is a perspective image view of the baffle plate 9g (9h, 9i), and FIG. 5B is a cross sectional image view of the baffle plate 9g (9h, 9i) taken along a vertical direction with respect to the center axis of the hollow cylindrical member 9c. As shown in these drawings, in the present embodiment, the openings 9ga (9ha, 9ia) are arranged in the radial direction with respect to the center axis of the hollow cylindrical member 9c.

Thus, multiple baffle plates 9g, 9h, 9i are formed to be in parallel to the center axis of the hollow cylindrical member 9c, so that the number of times of vortex formation much increases. Thus, the particle can be much captured. Accordingly, the effects according to the second embodiment are obtained.

### Fourth Embodiment

A fourth embodiment of the present disclosure will be explained. In the present embodiment, the construction of the baffle plates 9g-9i according to the third embodiment is changed. Other features are similar to the third embodiment. Thus, only different parts will be explained.

FIG. 6 is a cross sectional image view of the baffle plate 9g (9h, 9i) taken along a vertical direction with respect to the center axis of the hollow cylindrical member 9c.

In the above third embodiment, all of the openings 9ga, 9ha, 9ia formed in each baffle plate 9g-9i are arranged in the radial direction with respect to the center axis of the hollow cylindrical member 9c. It is not necessary for the openings 9ga, 9ha, 9ia to arrange in the radial direction. Accordingly, in the present embodiment, as shown in FIG. 6, one opening 9ga, 9ha, 9ia formed in one baffle plate 9g-9i is arranged to shift from another opening 9ga, 9ha, 9ia formed in adjacent baffle plate 9g-9i in a circumferential direction around the center axis of the hollow cylindrical member 9c. Thus, the openings are alternately arranged.

Thus, the number of sidewalls, on which the particle collides much more, increases. Further, since the flowing passage of the raw material gas 3 is elongated, the effects according to the second embodiment are obtained.

### Fifth Embodiment

A fifth embodiment of the present disclosure will be explained. In the present embodiment, the construction of the baffle plates 9g-9i according to the third embodiment is changed. Other parts are similar to the third embodiment. Only different parts will be explained.

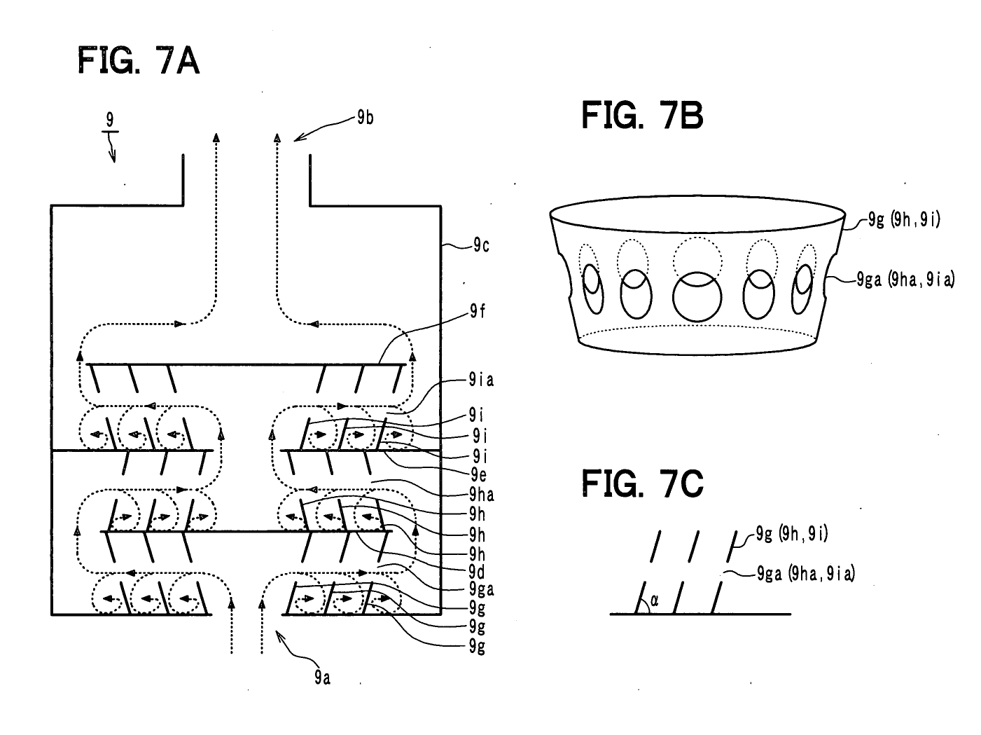

FIG. 7A is a cross sectional image view of the heating chamber 9 accommodated in the manufacturing device of the SiC single crystal according to the present embodiment. FIG. 7B is a perspective image view of one baffle plate 9g (9h, 9i), retrieved from the device. FIG. 7C is a partially enlarged cross sectional image view of the baffle plate 9g (9h, 9i).

As shown in the above drawings, in the present embodiment, the baffle plates 9g-9i have a hollow circular truncated cone shape. Each baffle plate 9g-9i slants with respect to the center axis of the hollow cylindrical member 9c and the baffle plates 9d-9f. Thus, the plate 9g-9i has a non-parallel structure. For example, a slant angle (i.e., a tapered angle) of each baffle plate 9g-9i with respect to the baffle plate 9d-9f is defined as α, as shown in FIG. 7C. The tapered angle α is in a range between 45 degrees and 80 degrees.

Thus, since each baffle plate 9g-9i slants with respect to the baffle plate 9d-9f, the captured particle is prevented from going out from the vortex of the gas flow. Thus, a capture rate of the particle increases. The effects according to the second embodiment are obtained easily.

### Sixth Embodiment

A sixth embodiment of the present disclosure will be explained. In the present embodiment, the structure of the openings 9ga-9ia in the baffle plates 9g-9i according to the second embodiment is changed. Other parts are similar to the second embodiment. Only different parts will be explained.

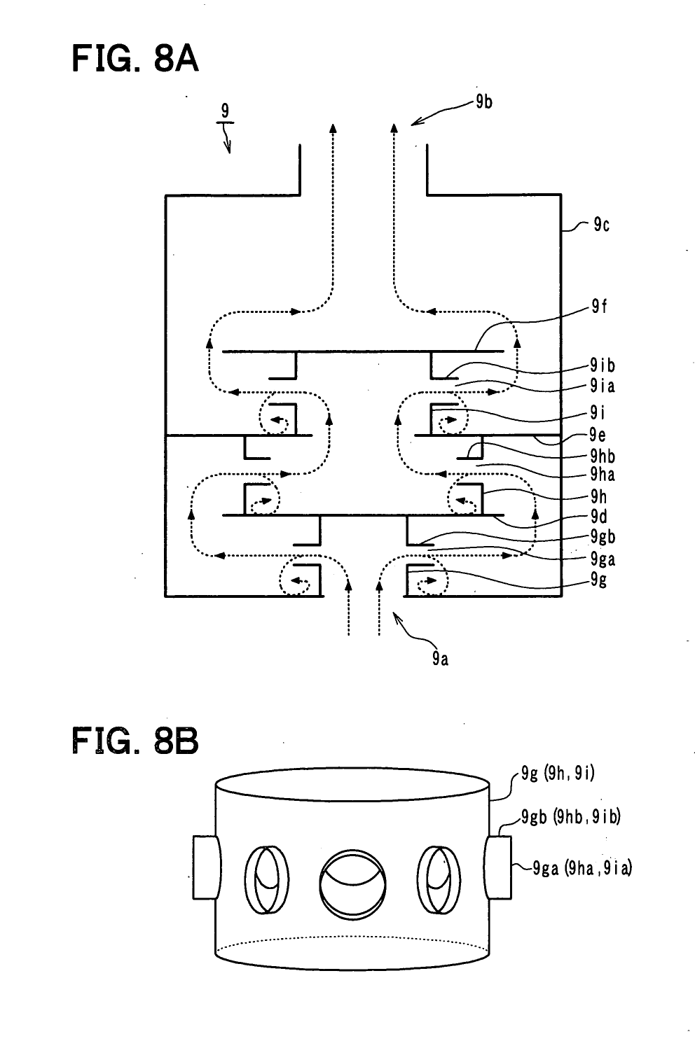

FIG. 8A is a cross sectional image view of the heating chamber r9 accommodated in the manufacturing device of the SiC single crystal according to the present embodiment. FIG. 8B is a perspective view of the baffle plate 9g (9h, 9i). Here, other parts of the manufacturing device of the SiC single crystal are similar to those in FIG. 1 according to the first embodiment.

As shown in FIGS. 8A and 8B, the openings 9ga-9ia are formed in each baffle plate 9g-9i, which is accommodated I the heating chamber 9. Further, a canopy portion 9gb, 9hb, 9ib is formed to surround a corresponding opening 9ga-9ia, and extends to the down stream side of the flowing direction of the raw material gas 3. The length of the canopy portion 9gb, 9hb, 9ib depends on the dimensions of the opening 9ga-9ia. For example, the length of the portion 9gb, 9hb, 9ib is about 10 millimeters.

When the baffle plate 9g-9i has the canopy portion 9gb-9ib, the canopy portion 9gb-9ib functions as a reverse portion so that the vortex of the raw material gas 3 is prevented from being returned to a main stream of the raw material gas 3, which flows through the opening 9ga-9ia. Accordingly, the capture rate of the particle much increases. Thus, the effects according to the second embodiment are obtained easily.

### Seventh Embodiment

A seventh embodiment of the present disclosure will be explained. In the present embodiment, the structure of the baffle plates 9g-9i according to the third embodiment is changed. Other parts are similar to the third embodiment. Only different parts will be explained.

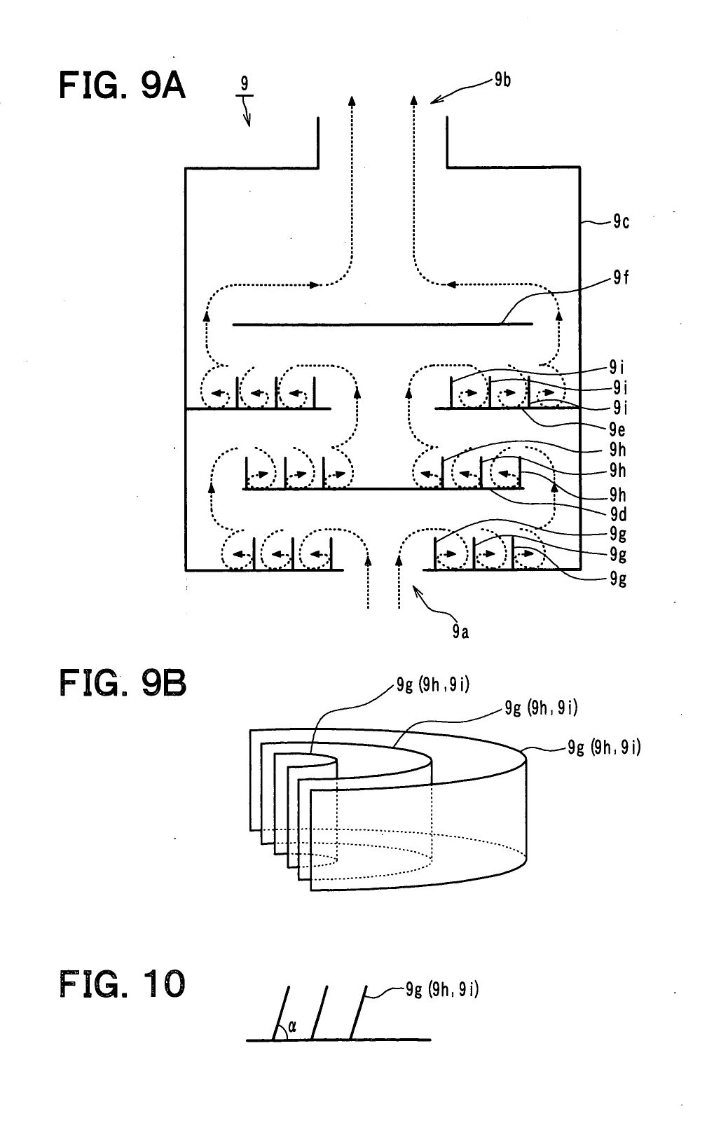

FIG. 9A is a cross sectional image view of the heating chamber 9 accommodated in the manufacturing device of the SiC single crystal according to the present embodiment. FIG. 9B is a perspective image view of the baffle plate 9g (9h, 9i). Here, other parts of the manufacturing device of the SiC single crystal are similar to those in FIG. 1 according to the first embodiment.

As shown in FIGS. 9A and 9B, in the present embodiment, the length of each baffle plate 9g-9i accommodated in the heating chamber 9 in a direction in parallel to the center axis of the hollow cylindrical member 9c is shortened so that the plate 9g-9i provides a fin shape. Thus, the baffle plate 9g does not reach the baffle plate 9d. The baffle plate 9h does not reach the baffle plate 9e, and the baffle plate 9i does not reach the baffle plate 9f. In such a case, the raw material gas 3 passes over the baffle plate 9g-9i. When the gas passes through the plate 9g-9i, the vortex is generated on the down stream side of the flowing direction of the raw material gas 3 from the corresponding baffle plate 9g-9i. The particle can be captured in the vortex. Accordingly, even when the plate 9g-9i has the above structure, the effects according to the third embodiment are obtained.

Here, the baffle plates 9g-9i having the above structure are easily formed since the baffle plates 9g-9i has no opening 9ga-9ia as described in the second embodiment. Further, a bonding portion for fixing the plate 9g-9i is small, so that forming steps of the heating chamber 9 are reduced. Here, in the present embodiment, each baffle plate 9g-9i has multiple plates, similar to the third embodiment. Alternatively, each baffle plate 9g-9i may have one plate, similar to the second embodiment.

### Eighth Embodiment

An eighth embodiment of the present disclosure will be explained. A construction of the baffle plates 9g-9i explained in the seventh embodiment is changed. Other parts are similar to the seventh embodiment. Only different parts will be explained.

FIG. 10 is a partially enlarged cross sectional image view of the baffle plate 9g (9h, 9i) in the heating chamber 9 accommodated in the manufacturing device of the SiC single crystal according to the present embodiment.

As shown in the above drawing, in the present embodiment, each baffle plate 9g-9i slants with respect to the center axis of the hollow cylindrical member 9c and the corresponding baffle plate 9d-9f. Thus, the plate 9g-9i has a non-parallel structure. For example, each baffle plate 9g-9i has a hollow circular truncated cone shape, so that the plate 9g-9i has the above structure. For example, the tapered angle α of each baffle plate 9g-9i with respect to the corresponding baffle plate 9d-9f is in a range between 45 degrees and 80 degrees.

Thus, since each baffle plate 9g-9i slants with respect to the corresponding baffle plate 9d-9f, the captured particle is prevented from going out from the vortex of the gas flow. Thus, a capture rate of the particle increases. Thus, the effects according to the seventh embodiment are obtained.

### Ninth Embodiment

A ninth embodiment of the present disclosure will be explained. In the present embodiment, the structure of the baffle plates 9g-9i according to the seventh embodiment is changed. Other parts are similar to the seventh embodiment. Only different parts will be explained.

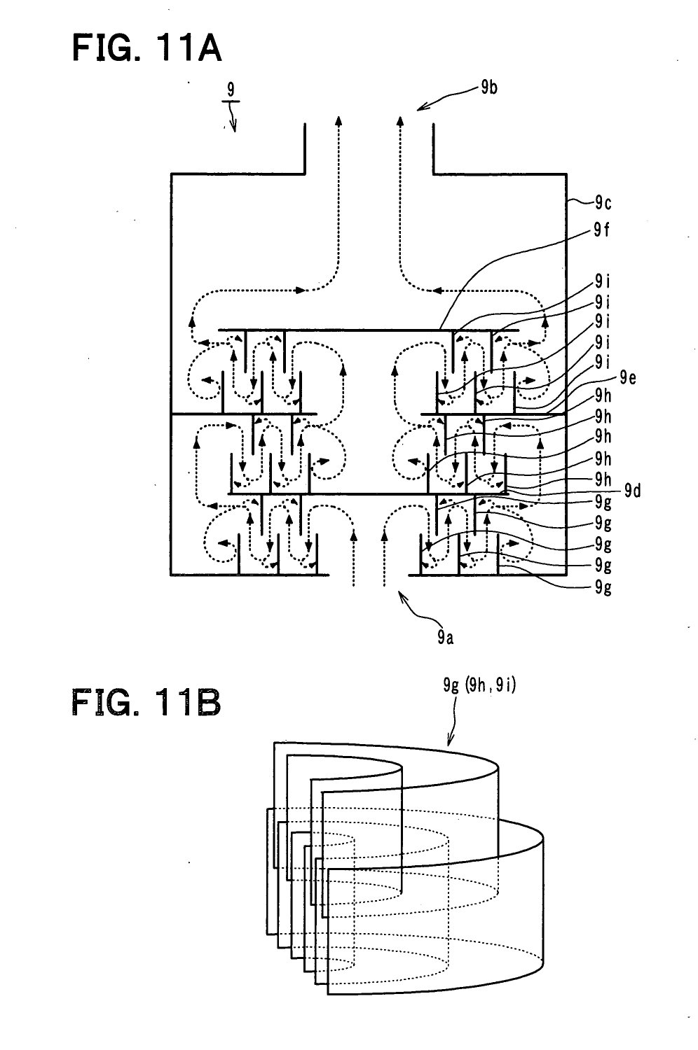

FIG. 11A is a cross sectional image view of the heating chamber 9 accommodated in the manufacturing device of the SiC single crystal according to the present embodiment. FIG. 11B is a perspective image view of the baffle plate 9g (9h, 9i). Here, other parts of the manufacturing device of the SiC single crystal are similar to those in FIG. 1 according to the first embodiment.

As shown in FIGS. 11A and 11B, adjacent baffle plates 9g-9i are alternately arranged to shift from each other in an up-down direction. Specifically, one of the baffle plates 9g is connected to the under side of the hollow cylindrical member 9c, and adjacent another one of the baffle plates 9g is connected to the baffle plate 9d. Thus, the baffle plate 9g includes the one and the other one alternately arranged. The baffle plate 9h includes one of the baffle plates 9h and adjacent another one of the baffle plates 9h alternately arranged, the one being connected to the baffle plate 9d, and the adjacent other one being connected to the baffle plate 9e. The baffle plate 9i includes one of the baffle plates 9i and adjacent another one of the baffle plates 9i alternately arranged, the one being connected to the baffle plate 9e, and the adjacent other one being connected to the baffle plate 9f.

Thus, since adjacent baffle plates 9g-9i shift from each other in the up-down direction. Thus, the flowing passage of the raw material gas 3 is lengthened. The effects according to the second embodiment are easily obtained.

### Tenth Embodiment

A tenth embodiment of the present disclosure will be explained. In the present embodiment, the construction of the baffle plates 9g-9i explained in the ninth embodiment is changed. Other parts are similar to the ninth embodiment. Only different parts will be explained.

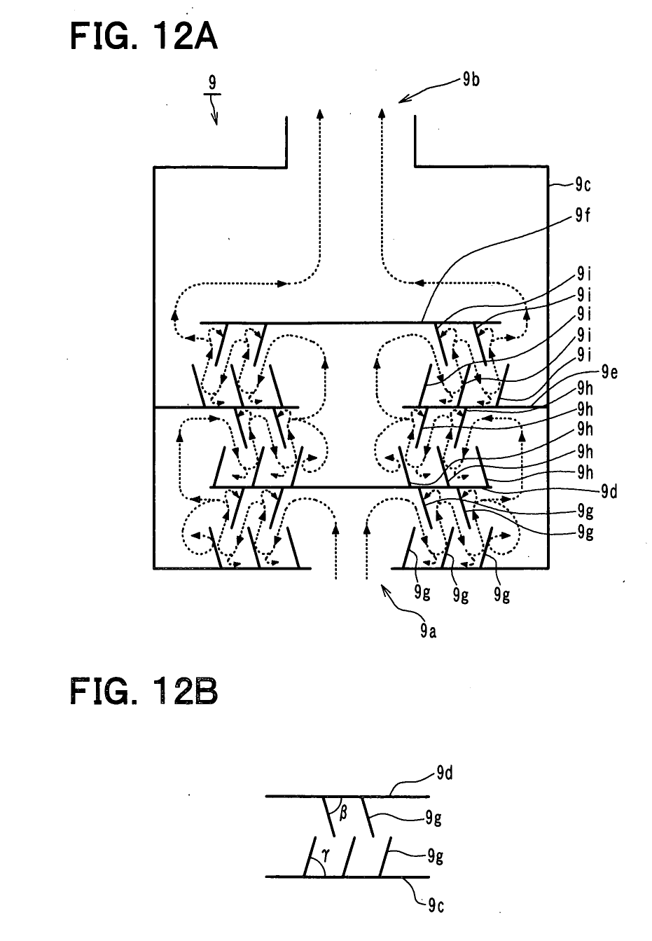

FIG. 12A is a cross sectional image view of the heating chamber 9 accommodated in the manufacturing device of the SiC single crystal according to the present embodiment. FIG. 12B is a partially enlarged cross sectional image view of baffle plate 9g (9h, 9i).

As shown in FIGS. 12A and 12B, in the present embodiment, each baffle plate 9g-9i slants with respect to the center axis of the hollow cylindrical member 9c and the corresponding baffle plate 9d-9f. Thus, the plate 9g-9i has a non-parallel structure. Specifically, a part of the baffle plates 9g-9i disposed on the under side has an upper end as a not-fixed end, which is positioned on the down stream side of the flowing direction of the raw material gas 3 from a lower end as a fixed end of the baffle plate 9g-9i. The other part of the baffle plates 9g-9i disposed on the upper side has a lower end as a not-fixed end, which is positioned on the down stream side of the flowing direction of the raw material gas 3 from an upper end as a fixed end of the baffle plate 9g-9i.

For example, as shown in FIG. 12B, the tapered angles of each baffle plate 9g-9i with respect to the corresponding baffle plate 9d-9f are defined as β and γ, respectively. The tapered angle β and the tapered angle γ are in a range between 45 degrees and 80 degrees, respectively.

Thus, each baffle plate 9g-9i slants with respect to the corresponding baffle plate 9d-9f. Thus, the captured particle is prevented from going out from the vortex of the gas flow. Thus, a capture rate of the particle increases. Thus, the effects according to the second embodiment are obtained.

### Eleventh Embodiment

An eleventh embodiment of the present disclosure will be explained. In the present embodiment, the construction of the baffle plates 9d-9f explained in the first embodiment is changed. Other parts are similar to the first embodiment. Only different parts will be explained.

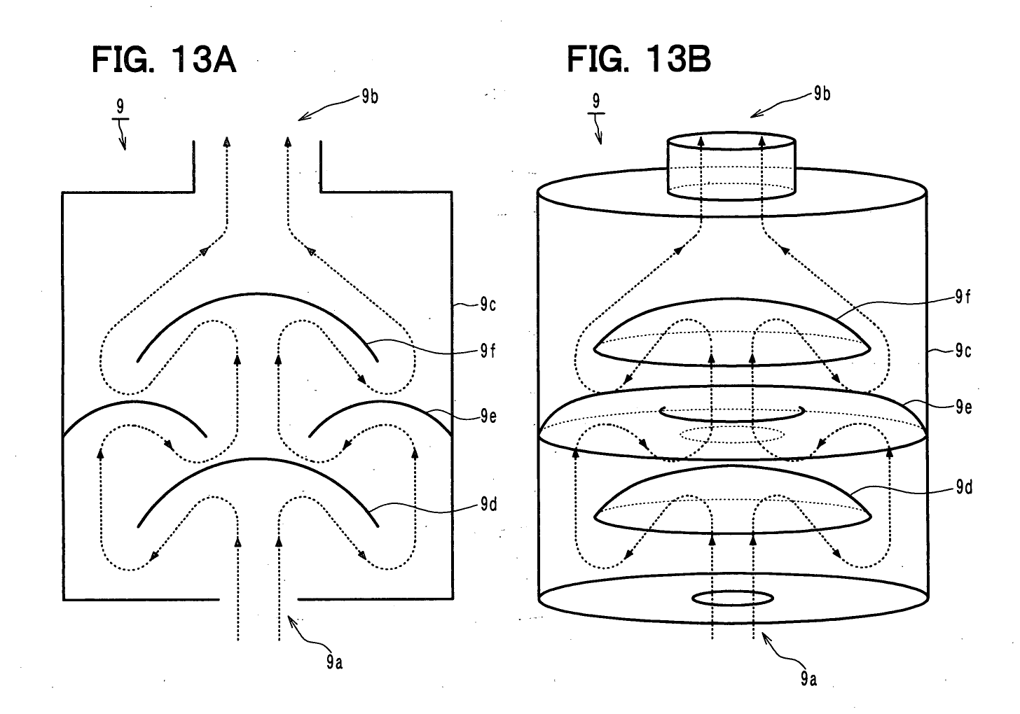

FIGS. 13A and 13B are cross sectional image view and a perspective image view of the heating chamber 9 accommodated in the manufacturing device of the SiC single crystal according to the present embodiment.

As shown in FIGS. 13A and 13B, in the present embodiment, a part of each baffle plate 9d-9i, on which the raw material gas 3 collides, has a dome shape with a convexity protruding upwardly (i.e., protruding toward the raw material gas supply nozzle 9b side). Thus, the raw material gas 3 flows along with the shape of each curved baffle plate 9d-9f, so that the length of the flowing passage of the raw material gas 3 is much lengthened. For example, the curvature of the convexity is, for example, in a range between 0.001 and 0.05.

Thus, the capture rate of the particle much increases. Further, a time interval, in which the raw material gas 3 is exposed in high temperature circumstance in the heated heating chamber 9, is much lengthened. Accordingly, the effects according to the first embodiment are obtained.

### Twelfth Embodiment

A twelfth embodiment of the present disclosure will be explained. In the present embodiment, the construction of the heating chamber 9 explained in the first embodiment is changed. Other parts are similar to the first embodiment. Only different parts will be explained.

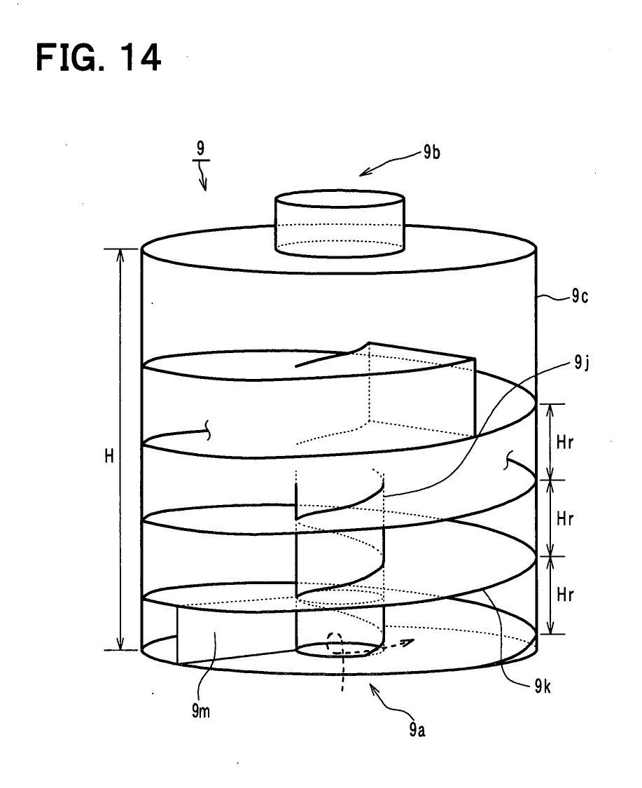

FIG. 14 is a perspective image view of the heating chamber 9 accommodated in the manufacturing device of the SiC single crystal according to the present embodiment.

As shown in the above drawing, in the present embodiment, the chamber 9 includes a spiral passage portion for providing the spiral flowing passage of the raw material gas 3 between the raw material gas inlet 9a and the raw material gas supply nozzle 9b. The spiral passage portion includes a column shaft 9j arranged concentrically around the center of the center axis of the hollow cylindrical member 9c, and a slant plate 9k extending from the column shaft 9j to an inner wall of the hollow cylindrical member 9c and winded in a spiral manner around a center of the column shaft 9j. The slant plate 9k is winded from the bottom of the hollow cylindrical member 9c multiple times around the center axis of the hollow cylindrical member 9c as a center. Then, the slant plate 9k has a structure such that the plate 9k is disconnected before the plate 9k reaches the upper side of the hollow cylindrical member 9c. Accordingly, a back room for diffusing the raw material gas 3 is formed in a region of the hollow cylindrical member 9c, in which the slant plate 9k is not formed. Thus, the raw material gas 3 is discharged from the raw material gas supply nozzle 9b under a condition that the vortex of the raw material gas 3 is restricted.

Here, at least one end of the column shaft 9j on the raw material gas inlet 9a side is closed at a position, which is spaced apart from the raw material gas inlet 9a by a predetermined distance. Accordingly, the raw material gas 3 introduced from the raw material gas inlet 9a collides on the one end of the shaft 9j, and then, the gas 3 ascends along the slant plate 9k. Further, a closed wall 9m is formed at a position, which is separated from a boundary between the slant plate 9k and the bottom of the hollow cylindrical member 9c. The wall 9m restricts the flowing direction of the raw material gas 3 so that the raw material gas 3 introduced from the raw material gas inlet 9a flows to the slant plate 9k side.

In the heating chamber 9 having the above construction, the number of windings of the slant plate 9k and a distance Hr are set in such a manner that the average flowing passage length f as an average of the length of the flowing passage of the raw material gas 3 has a relationship of f>1.2H, compared with the dimension H of the hollow cylindrical member 9c in the center axis direction. Here, the average flowing passage length f means a length of the flowing passage assuming that the raw material gas 3 flows at a center of the passage, which is provided by the slant plate 9k. Further, in the present embodiment, the distance Hr between the slant plate 9k, which is arranged in a spiral manner, is constant. Alternatively, the distance Hr may be expanded as the passage reaches the upper side so that the flowing speed on the under side is rapid, and the flowing speed on the upper side is gentle.

Thus, since the flowing passage having the spiral shape is formed in the heating chamber 9, the flowing passage of the raw material gas 3 is lengthened. Thus, a time interval, in which the gas 3 is exposed in high temperature circumstance in the heated heating chamber 9, is lengthened. Accordingly, the effects according to the first embodiment are obtained.

### Thirteenth Embodiment

A thirteenth embodiment of the present disclosure will be explained. In the present embodiment, an additional baffle plate is formed, compared with the twelfth embodiment. Other parts are similar to the twelfth embodiment. Only different parts will be explained.

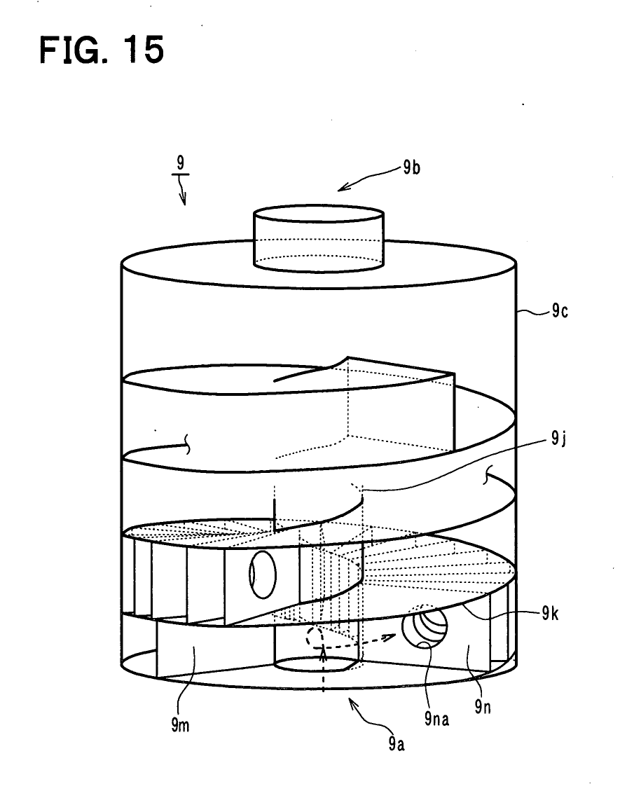

FIG. 15 is a perspective image view of the heating chamber 9 accommodated in the manufacturing device of the SiC single crystal according to the present embodiment. Here, other parts of the manufacturing device of the SiC single crystal are similar to those in FIG. 1 according to the first embodiment.

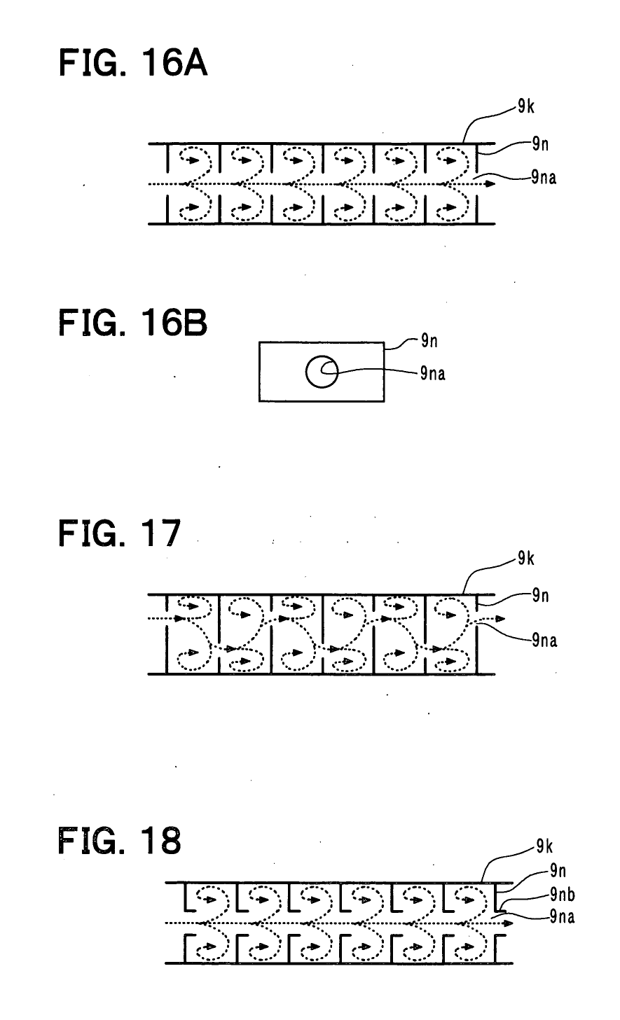

As shown in FIG. 15, the heating chamber 9 includes multiple baffle plates (as sub baffle plates) 9n, which extends from the column shaft 9j in a radial direction of the center axis of the hollow cylindrical member 9c, and intersects with the slant plate 9k. Specifically, in the present embodiment, the baffle plate 9n is in parallel to the center axis and the radial direction of the hollow cylindrical member 9c. Further, the plate 9n connects between the slant plate 9k, in which the baffle plate 9n is arranged. FIG. 16A is a cross sectional view of a center portion of the flowing passage of the raw material gas 3 in the heating chamber 9 taken along the center axis direction of the hollow cylindrical member 9c. FIG. 16B is a front view of one baffle plate 9n. As shown in FIGS. 16A and 16B, each baffle plate 9n has an opening 9na. In the present embodiment, the opening 9na is formed at a center portion of the baffle plate 9n. The shape of the opening 9na may be any. In the present embodiment, the opening 9na has a circular shape with a diameter φ in a range between 10 millimeters and 30 millimeters. It is preferable that the area of the opening 9na is equal to or smaller than a half of the area of the baffle plate 9n so that the baffle plate 9n sufficiently functions to interrupt the raw material gas 3 flow.

In the manufacturing device of the SiC single crystal having the above structure, the raw material gas 3 flows through the opening 9na. At this time, when the raw material gas 3 passes through the baffle plate 9n, the flowing passage is narrowed so that the flowing speed increases. Accordingly, the particle easily collides on the baffle plate 9n. Further, as shown with an arrow in FIG. 16A, the vortex is generated in the gas flow on the down stream side of the flowing direction of the raw material gas 3 with respect to each baffle plate 9n. The particle is captured by the vortex. Thus, the particle is accumulated at a under portion on the down stream side of the flowing direction. Thus, the time interval, in which the particle is exposed in high temperature circumstance, is much lengthened. Accordingly, the particle is effectively decomposed and disappeared. Further, the decomposed particle may be merged into the raw material gas 3 again so that the particle provides growing material. Even if the particle is persistent, the particle is continuously captured in the vortex. Thus, the particle is prevented from being attached to the growing surface of the SiC single crystal 6, and therefore, the device manufactures the SiC single crystal 6 with high quality.

### Fourteenth Embodiment

A fourteenth embodiment of the present disclosure will be explained. In the present embodiment, the arrangement position of the opening 9na in the baffle plate 9n explained in the thirteenth embodiment is changed. Other parts are similar to the thirteenth embodiment. Only different parts will be explained.

FIG. 17 is a cross sectional view of the center portion of the flowing passage of the raw material gas 3 in the heating chamber 9, which is accommodated in the manufacturing device of the SiC single crystal according to the present embodiment, the center portion taken along the center axis direction of the hollow cylindrical member 9c.

As shown in the above drawing, forming positions of the openings 9na in adjacent baffle plates 9n are different from each other, so that the openings 9na are positioned to shift from each other when the adjacent baffle plates 9n are arranged on the slant plate 9k.

Thus, since the forming positions of the openings 9na in adjacent baffle plates 9n are different from each other, a distance between the openings 9n is lengthened, compared with a case where the forming positions of the openings 9na are same. Accordingly, as shown with an arrow in the drawing, the flowing passage of the raw material gas 3 is not merely the spiral shape but curved between the baffle plates 9n. Thus, the passage is lengthened, compared with the thirteenth embodiment. Thus, the particle is captured effectively. Further, a time interval, in which the raw material gas 3 is exposed in high temperature circumstance, is lengthened. Accordingly, the particle is effectively decomposed and disappeared. Thus, the effects according to the thirteenth embodiment are obtained.

### Fifteenth Embodiment

A fifteenth embodiment of the present disclosure will be explained. In the present embodiment, the structure of the opening 9na in the baffle plate 9n according to the thirteenth and fourteenth embodiments is changed. Other parts are similar to the second embodiment. Only different parts will be explained.

FIG. 18 is a cross sectional view of the center portion of the flowing passage of the raw material gas 3 in the heating chamber 9, which is accommodated in the manufacturing device of the SiC single crystal according to the present embodiment, the center portion taken along the center axis direction of the hollow cylindrical member 9c.

As shown in FIG. 18, each baffle plate 9n in the heating chamber 9 includes an opening 9na. Further, the plate 9n includes a canopy portion 9nb, which extends to the down stream side of the flowing direction of the raw material gas 3 with respect to each opening 9na. The length of the canopy portion 9nb depends on the dimensions of the opening 9na. For example, the length of the portion 9nb is about 10 millimeters.

When the plate 9n includes the canopy portion 9nb, the canopy portion 9nb functions as a reverse portion so that the vortex of the raw material gas 3 is prevented from being returned to a main stream of the raw material gas 3, which flows through the opening 9na. Accordingly, the capture rate of the particle much increases. Thus, the effects according to the thirteenth and fourteenth embodiments are obtained easily.

### Sixteenth Embodiment

A sixteenth embodiment of the present disclosure will be explained. In the present embodiment, the structure of the baffle plate 9n according to the thirteenth embodiment is changed. Other parts are similar to the thirteen embodiment. Only different parts will be explained.

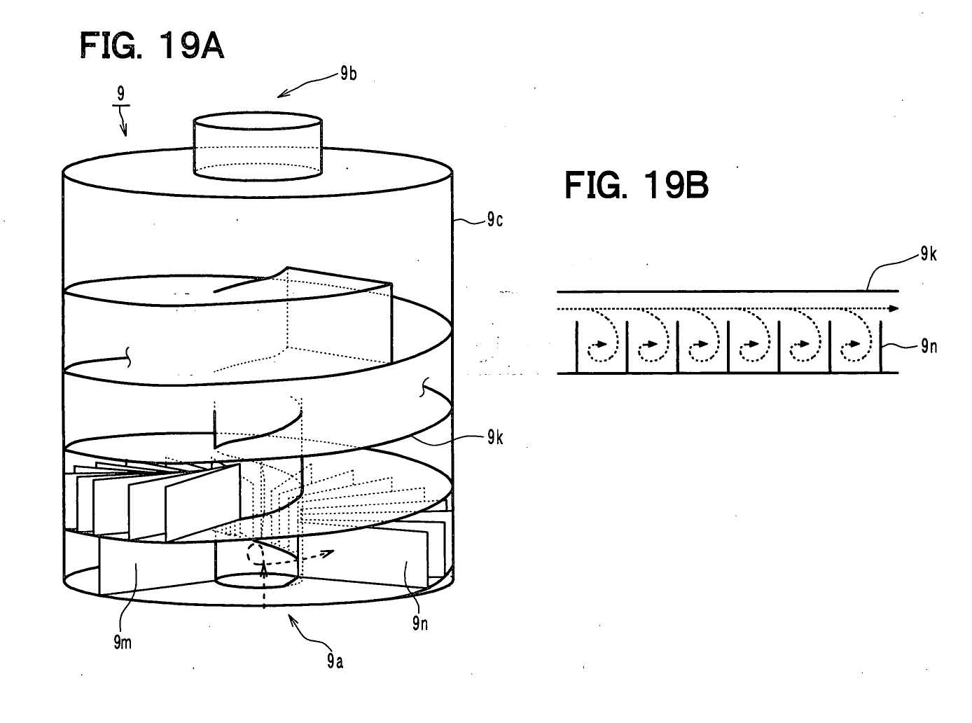

FIG. 19A is a perspective image view of the heating chamber 9 accommodated in the manufacturing device of the SiC single crystal according to the present embodiment. FIG. 19B is a cross sectional view of a center portion of the flowing passage of the raw material gas 3 in the heating chamber 9 taken along the center axis direction of the hollow cylindrical member 9c. Other parts of the manufacturing device of the SiC single crystal are similar to those in FIG. 1 according to the first embodiment.

As shown in FIGS. 19A and 19B, in the present embodiment, the length of each baffle plate 9n accommodated in the heating chamber 9 in a direction in parallel to the center axis of the hollow cylindrical member 9c is shortened so that the plate 9n provides a fin shape. Thus, the baffle plate 9n does not reach the backside of the baffle plate 9k, which is disposed over the baffle plate 9n. In such a construction, the raw material gas 3 passes over the baffle plate 9n. When the gas passes through the plate 9n, the vortex is generated on the down stream side of the flowing direction of the raw material gas 3 from the corresponding baffle plate 9n. The particle can be captured in the vortex. Accordingly, even when the plate 9n has the above structure, the effects according to the thirteenth embodiment are obtained.

Here, the baffle plate 9n having the above structure is easily formed since the plate 9n does not include the opening 9na according to the thirteenth embodiment or the like. Further, a bonding portion for fixing the plate 9n is small, so that forming steps of the heating chamber 9 are reduced.

### Seventeenth Embodiment

A seventeenth embodiment of the present disclosure will be explained. In the present embodiment, the construction of the baffle plate 9n explained in the sixteenth embodiment is changed. Other parts are similar to the sixteenth embodiment. Only different parts will be explained.

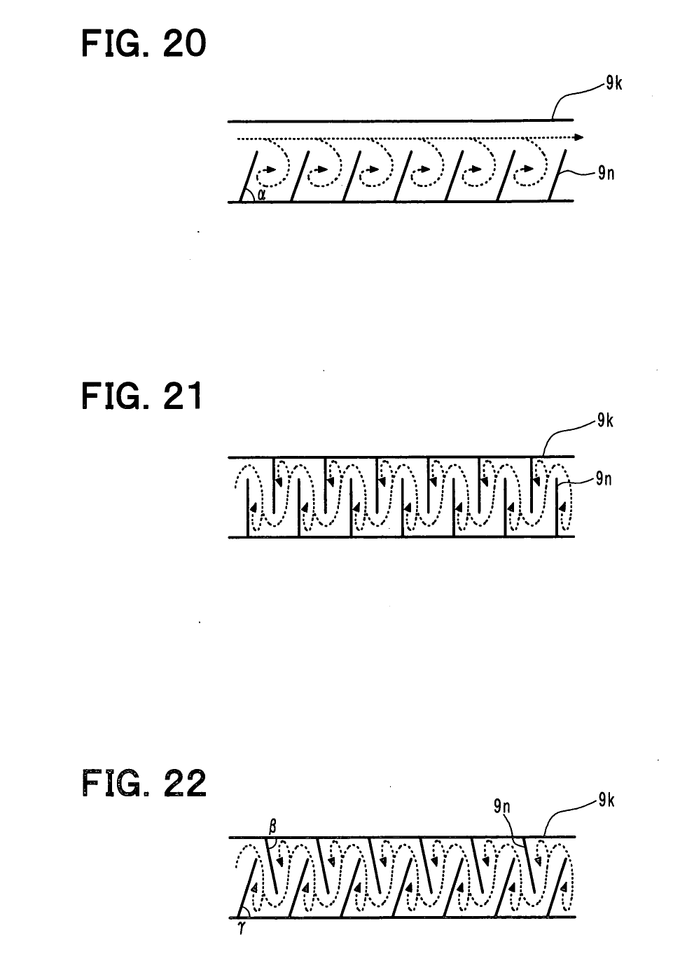

FIG. 20 is a cross sectional view of a center portion of the flowing passage of the raw material gas 3 in the heating chamber 9 accommodated in the manufacturing device of the SiC single crystal according to the present embodiment, the center portion taken along the center axis direction of the hollow cylindrical member 9c.

As shown in the above drawing, in the present embodiment, each baffle plate 9n slants with respect to the slant plate 9k, so that the plate 9n has a non-parallel structure. Specifically, the upper end of each baffle plate 9n is disposed on the down stream side of the flowing direction of the raw material gas 3 from the lower end of the plate 9n. Thus, each baffle plate 9n slants, and a tapered angle α is formed with respect to the slant plate 9k. For example, the tapered angle α of each baffle plate 9n with respect to the slant plate 9k is in a range between 45 degrees and 80 degrees.

Thus, each baffle plate 9n has a structure such that the plate 9n slants with respect to the slant plate 9k. Thus, the captured particle is prevented from going out from the vortex of the gas flow. Thus, a capture rate of the particle increases. Thus, the effects according to the thirteenth embodiment are obtained.

### Eighteenth Embodiment

An eighteenth embodiment of the present disclosure will be explained. In the present embodiment, the construction of the baffle plate 9n according to the seventeenth embodiment is changed. Other parts are similar to the seventeenth embodiment. Only different parts will be explained.

FIG. 21 is a cross sectional view of a center portion of the flowing passage of the raw material gas 3 in the heating chamber 9 accommodated in the manufacturing device of the SiC single crystal according to the present embodiment, the center portion taken along the center axis direction of the hollow cylindrical member 9c.

As shown in FIG. 21, two adjacent baffle plates 9n are alternately arranged to shift from each other in an up-down direction. Specifically, one of the baffle plates 9n connected to the front surface of the slant plate 9k and the other of the baffle plates 9n connected to the backside surface of the slant plate 9k are alternately arranged.

Thus, since two adjacent baffle plates 9n are alternately arranged to shift from each other in the up-down direction, the flowing passage of the raw material gas 3 is lengthened. Thus, the effects according to thirteenth embodiment are obtained easily.

### Nineteenth Embodiment

A nineteenth embodiment of the present disclosure will be explained. In the present embodiment, the construction of the baffle plate 9n explained in the eighteenth embodiment is changed. Other parts are similar to the eighteenth embodiment. Only different parts will be explained.

FIG. 22 is a cross sectional view of a center portion of the flowing passage of the raw material gas 3 in the heating chamber 9 accommodated in the manufacturing device of the SiC single crystal according to the present embodiment, the center portion taken along the center axis direction of the hollow cylindrical member 9c.

As shown in FIG. 22, in the present embodiment, each baffle plate 9n slants with respect to the slant plate 9k, so that the plate 9n has a non-parallel structure. Specifically, a part of the baffle plates 9n disposed on the front surface of the slant plate 9k has an upper end as a not-fixed end, which is positioned on the down stream side of the flowing direction of the raw material gas 3 from a lower end as a fixed end of the baffle plate 9n. The other part of the baffle plates 9n disposed on the backside surface of the slant plate 9k has a lower end as a not-fixed end, which is positioned on the down stream side of the flowing direction of the raw material gas 3 from an upper end as a fixed end of the baffle plate 9n. For example, as shown in FIG. 22, the tapered angles of each baffle plate 9n with respect to the backside surface or the front surface of the slant plate 9k are defined as β and γ, respectively. The tapered angle β and the tapered angle γ are in a range between 45 degrees and 80 degrees, respectively.

Thus, each baffle plate 9n has a structure such that the baffle plate 9n slants with respect to the front surface or the backside surface of the corresponding slant plate 9k. Thus, the captured particle is prevented from going out from the vortex of the gas flow. Thus, a capture rate of the particle increases. Thus, the effects according to the thirteenth embodiment are obtained.

### Twentieth Embodiment

A twentieth embodiment of the present disclosure will be explained. In the present embodiment, the back room for diffusing the raw material gas 3 includes a rectifier function for rectifying the gas flow of the raw material gas 3 in a direction toward the raw material gas supply nozzle 9b. Other features are similar to the twelfth embodiment. Only different parts from the twelfth embodiment will be explained.

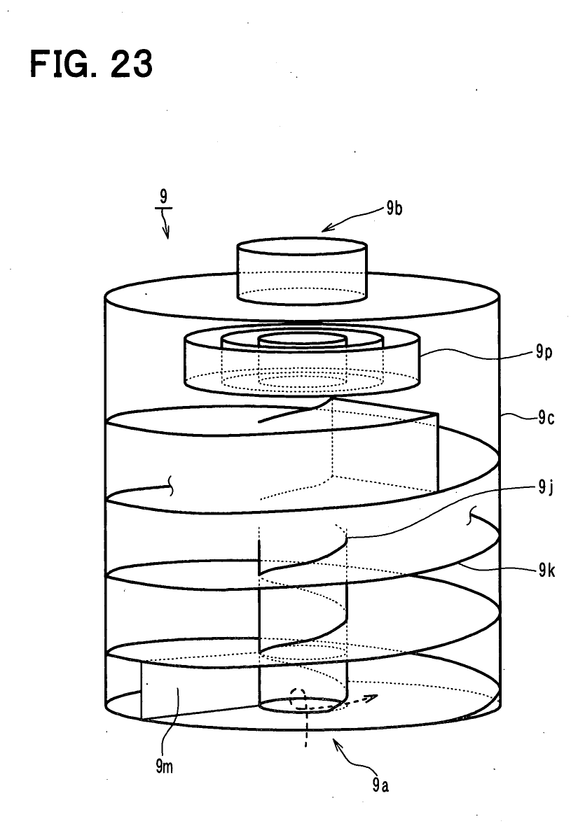

FIG. 23 is a perspective image view of the heating chamber 9 accommodated in the manufacturing device of the SiC single crystal according to the present embodiment.

As shown in the above drawing, the back room for diffusing the raw material gas 3 is formed in a region of the hollow cylindrical member 9c, in which the slant plate 9k is not formed. In the back room, a rectifier system 9p is formed. The rectifier system 9p rectifies the gas flow of the raw material gas 3 before the gas 3 reaches the raw material gas supply nozzle 9b. The rectifier system 9p is arranged between the upper side of the hollow cylindrical member 9c and the slant plate 9k. In the present embodiment, the system 9p includes multiple ring members, which are arranged concentrically.

Thus, since the rectifier system 9p is formed before the raw material gas supply nozzle 9b, the rectified raw material gas 3 not the vortex is supplied to the growing surface of the SiC single crystal 6. Thus, the SiC single crystal 6 having high quality is grown.

### Other Embodiments

In the above third and fourth embodiments, the number of openings 9ga, 9ha, 9ia formed in the baffle plates 9g-9i is same. Alternatively, the number may be different from each other. Further, the number of plates in each baffle plate 9g-9i is three, and the number is same. Alternatively, the number may be different from each other. Further, only a part of the baffle plates 9g-9i may include multiple plates.

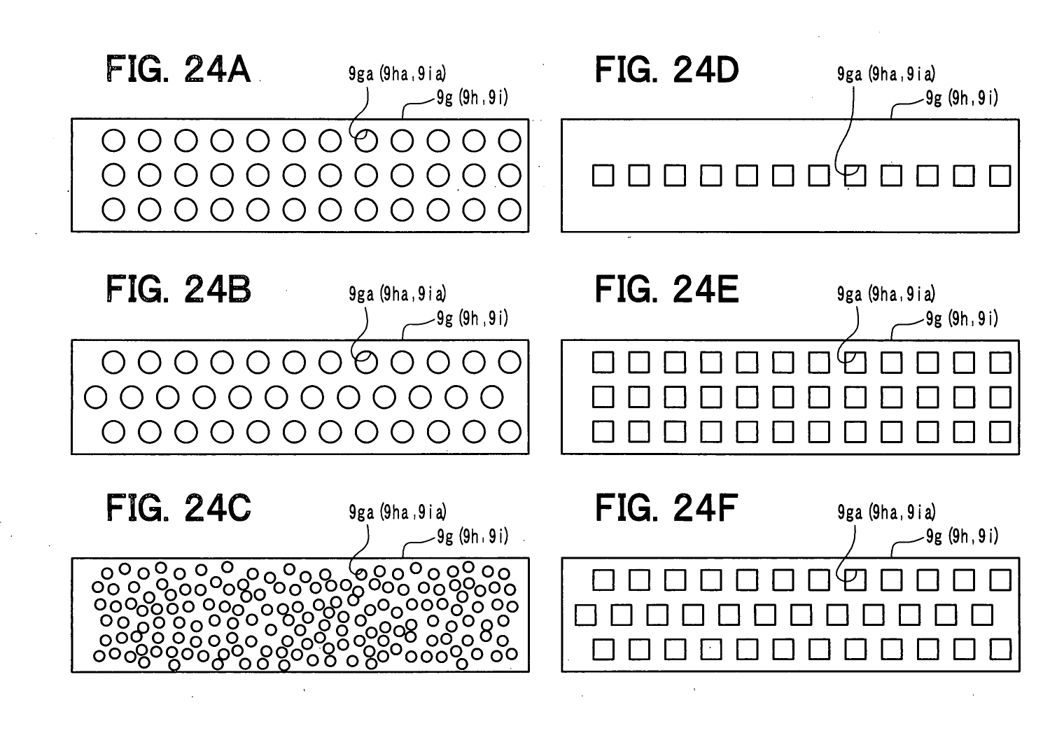

In the second to fourth embodiments, the openings 9ga, 9ha, 9ia are aligned in one line in the circumferential direction around a center of the center axis of the hollow cylindrical member 9c. It is not necessary for the openings 9ga, 9ha, 9ia to have the above structure. For example, as shown in FIG. 24A, the openings 9ga, 9ha, 9ia may be aligned in multiple lines. Alternatively, as shown in 24B, even when the openings 9ga, 9ha, 9ia are aligned in multiple lines, the lines of the openings 9ga, 9ha, 9ia may be arranged to shift from each other in the circumferential direction around a center of the center axis of the hollow cylindrical member 9c. Alternatively, as shown in FIG. 24C, a great number of openings 9ga, 9ha, 9ia may be formed such that formation positions of the openings 9ga, 9ha, 9ia are at random.

In the second to fourth embodiments, each opening 9ga, 9ha, 9ia formed in each baffle plate 9g-9i shown in each embodiment has a circular shape. The opening 9ga, 9ha, 9ia may have other shapes. For example, as shown in FIG. 24D, the opening 9ga, 9ha, 9ia may have a square shape. Alternatively, the opening 9ga, 9ha, 9ia may have a triangle or hexagonal shape. In these cases, as shown in FIG. 24E, the openings 9ga, 9ha, 9ia may be aligned in multiple lines. Alternatively, as shown in FIG. 24F, the lines of the openings 9ga, 9ha, 9ia may be arranged to shift from each other in the circumferential direction around a center of the center axis of the hollow cylindrical member 9c. Alternatively, a great number of openings may be formed.

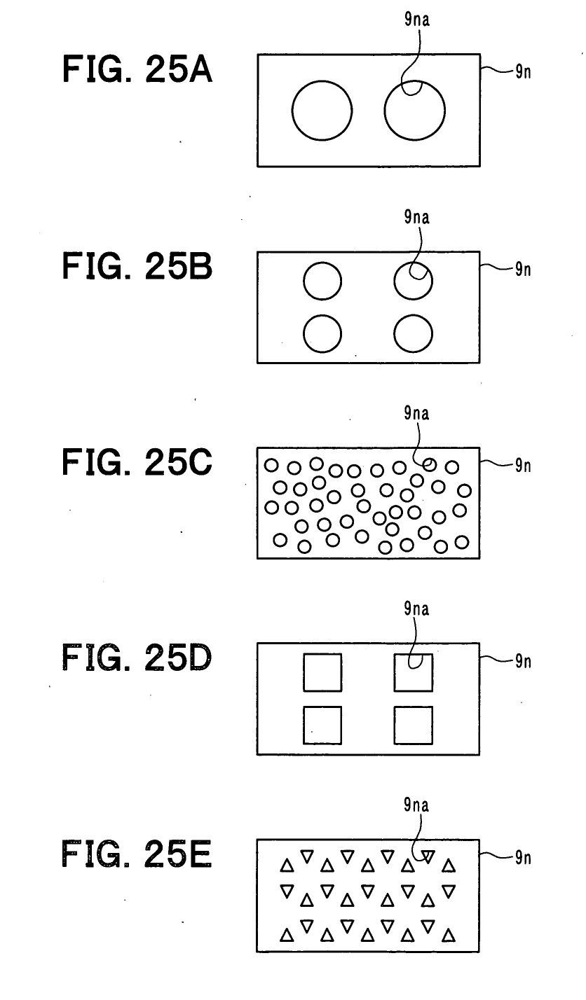

Further, the number and the shape of the openings 9na formed in each baffle plate 9n explained in the thirteenth to fifteenth embodiments may be any. For example, as shown in FIG. 25A, two openings 9na may be formed in each baffle plate 9n. Alternatively, four openings 9na may be formed, as shown in FIG. 25B. Alternatively, as shown in FIG. 25C, a great number of openings 9na may be formed. Alternatively, as shown in FIG. 25D, the opening 9na may have a square shape. Alternatively, as shown in FIG. 25E, the opening 9na may have a triangle shape.

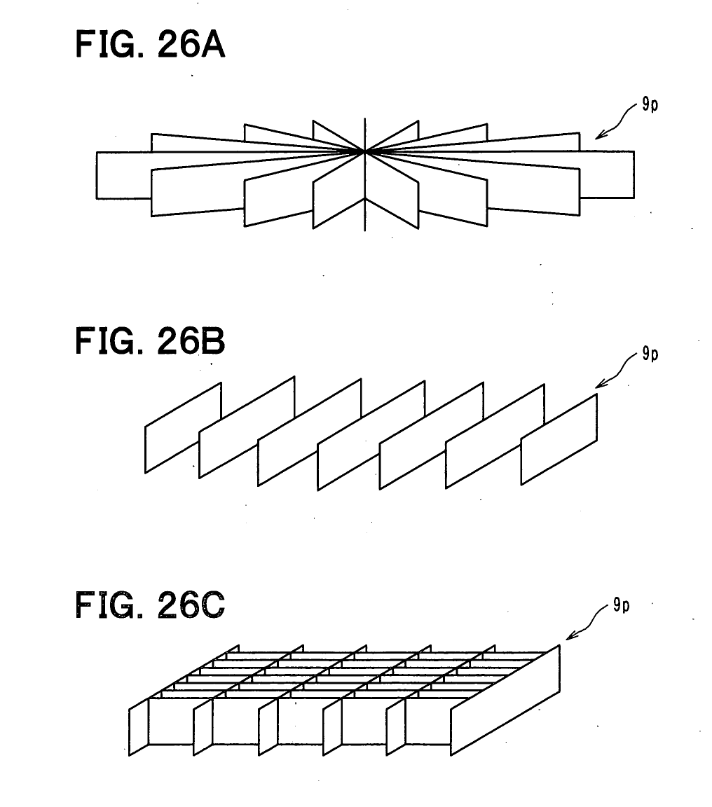

In the twentieth embodiment, the rectifier system 9p is provided by, for example, multiple ring members, which are arranged concentrically. The system 9p may have other shapes. For example, as shown in FIG. 26A, the system 9p may be provided by multiple plate members, which extend from a center of the center axis of the hollow cylindrical member 9c in the radial direction at equal intervals. Alternatively, as shown in FIG. 26B, the system 9p may be provided by multiple plate members, which are arranged in parallel to each other. Alternatively, as shown in FIG. 26C, the system 9p may be provided by a plate member arranged in a grid manner (in a lattice manner).

Each embodiment merely describes one example of the heat chamber 9. Thus, it is possible to combine the embodiments. For example, in the structure having the baffle plates 9g-9i according to the second embodiment, a part of each baffle plate 9d-9i, on which the raw material gas 3 collides, has a dome shape with a convexity protruding upwardly (i.e., protruding toward the raw material gas supply nozzle 9b side) according to the eleventh embodiment.

The above disclosure has the following aspects.

According to a first aspect of the present disclosure, a manufacturing device of a silicon carbide single crystal includes: a reaction chamber; a seed crystal made of a silicon carbide single crystal substrate and arranged in the reaction chamber; and a heating chamber for heating a raw material gas. The seed crystal is disposed on an upper side of the reaction chamber. The raw material gas is supplied from an under side of the reaction chamber so that the gas reaches the seed crystal, and the silicon carbide single crystal is grown on the seed crystal. The heating chamber is disposed on an upstream side of a flowing passage of the raw material gas from the reaction chamber. The heating chamber includes a hollow cylindrical member, a raw material gas inlet, a raw material gas supply nozzle and a plurality of baffle plates. The raw material gas inlet introduces the raw material gas into the hollow cylindrical member. The raw material gas supply nozzle discharges the raw material gas from the hollow cylindrical member to the reaction chamber. The plurality of baffle plates are arranged on the flowing passage of the raw material gas between the raw material gas inlet and the raw material gas supply nozzle.

Thus, the plurality of baffle plates are arranged on the flowing passage of the raw material gas between the raw material gas inlet and the raw material gas supply nozzle. Accordingly, the raw material gas including a particle collides on the plurality of baffle plates, which are arranged on the flowing passage of the raw material gas between the raw material gas inlet and the raw material gas supply nozzle. The flowing direction of the raw material gas is changed many times so that the gas flows in a flowing passage length, which is longer than a case where the baffle plate is not arranged and a case where one baffle plate is arranged in one stage manner. Accordingly, a time interval, in which the raw material gas is exposed in high temperature circumstance in the heated heating chamber 9, is lengthened. Accordingly, the particle is decomposed, and the particle does not reach a surface of the seed crystal and a growing surface of the SiC single crystal. Thus, the device manufactures the SiC single crystal with high quality.

Alternatively, the heating chamber has an average flowing passage length of the raw material gas, which is defined as f. The average flowing passage length is an average length of the flowing passage of the raw material gas in the heating chamber. The average flowing passage length and a direct distance between the raw material gas inlet and the raw material gas supply nozzle defined as H has a relationship of f>1.2H.

Alternatively, the plurality of baffle plates intersect with a center axis of the hollow cylindrical member and are arranged in a multiple stage manner along with the center axis as an arrangement direction. The plurality of baffle plates includes an utmost under baffle plate disposed nearest the raw material gas inlet. The utmost under baffle plate covers the raw material gas inlet seeing from an upper side of the heating chamber. In the above case, the raw material gas introduced from the raw material gas inlet surely collides on the utmost under baffle plate.

Alternatively, the plurality of baffle plates includes an utmost upper baffle plate disposed nearest the raw material gas supply nozzle. The utmost upper baffle plate covers the raw material gas supply nozzle seeing from a under side of the heating chamber. In the above case, the raw material gas surely collides on an upper portion of the hollow cylindrical member before the gas reaches the raw material gas supply nozzle.

Alternatively, the plurality of baffle plates includes a plurality of middle baffle plates disposed between the utmost under baffle plate and the utmost upper baffle plate. The middle baffle plates include a middle baffle plate having a circular shape and another middle baffle plate having a ring shape. The middle baffle plate having the circular shape is adjacent to the utmost under baffle plate. The other middle baffle plate having the ring shape is adjacent to the middle baffle plate having the circular shape. The other middle baffle plate having the ring shape includes an opening. The middle baffle plate having the circular shape and the other middle baffle plate having the ring shape are repeatedly and alternately arranged. A radius of the middle baffle plate having the circular shape is larger than a radius of the opening of the other middle baffle plate having the ring shape, which is disposed under the middle baffle plate having the circular shape. In the above case, the raw material gas surely collides on the middle baffle plate, so that the flowing passage of the raw material gas is changed.

Alternatively, a distance between two adjacent baffle plates disposed on the upper side is equal to or larger than a distance between two adjacent baffle plates disposed on the under side. In the above case, a flowing speed of the raw material gas increases at the raw material gas inlet, and the flowing speed of the gas is reduced gradually toward the raw material gas supply nozzle. Thus, the particle is captured effectively.

Alternatively, the manufacturing device further includes: a plurality of sub baffle plates. The plurality of sub baffle plates are disposed between two adjacent baffle plates arranged in the multiple stage manner, and disposed between a bottom of the hollow cylindrical member and the utmost under baffle plate. Each sub baffle plate intersects with the baffle plates arranged in the multiple stage manner. Each sub baffle plate extends in a direction intersecting with a radial direction with respect to the center axis of the hollow cylindrical member. Thus, the plurality of multiple baffle plates may further include a plurality of sub baffle plates, which are disposed between two adjacent baffle plates arranged in the multiple stage manner, and/or disposed between a bottom of the hollow cylindrical member and the utmost under baffle plate. Thus, a vortex is generated in the gas flow, on the down stream side of the flowing direction of the raw material gas with, respect to each sub baffle plate. The particle is captured by the vortex. Thus, the particle is accumulated at a under portion on the down stream side of the flowing direction. Thus, the time interval, in which the raw material gas is exposed in high temperature circumstance, is much lengthened. Accordingly, the particle is effectively decomposed and disappeared. Further, the decomposed particle may be merged into the raw material gas again so that the particle provides growing material. Even if the particle is persistent, the particle is continuously captured in the vortex. Thus, the particle is prevented from being attached to the growing surface of the SiC single crystal, and therefore, the device manufactures the SiC single crystal with high quality.

Alternatively, each sub baffle plate has a cylindrical shape around center axis of the hollow cylindrical member. Each sub baffle plate connects between two adjacent baffle plates arranged in the multiple stage manner, and between the bottom of the hollow cylindrical member and the utmost under baffle plate. Each sub baffle plate has an opening for providing the flowing passage of the raw material gas. In the above case, the raw material gas is flown through multiple openings. When the raw material gas passes through the sub baffle plate, the flowing passage of the gas is narrowed, so that the flowing speed increases. Accordingly, the particle easily collides on the sub baffle plate.

Alternatively, each sub baffle plate disposed between two adjacent baffle plates arranged in the multiple stage manner, and disposed between the bottom of the hollow cylindrical member and the utmost under baffle plate includes a predetermined number of plates. Thus, since the predetermined number of plates in each sub baffle plate are arranged, the number of times of formation of the vortex increases. Thus, the particle is captured frequently.

Further, the openings of the predetermined number of plates of each sub baffle plate are arranged side-by-side in the radial direction with respect to the center axis of the hollow cylindrical member. Alternatively, the openings of two adjacent plates of each sub baffle plate are arranged to shift from each other in a circumferential direction around the center axis of the hollow cylindrical member. Thus, the number of the inner walls, on which the particle collides, increases. Further, the flowing passage length of the raw material gas is lengthened. Thus, the particle is frequently captured.

Alternatively, each sub baffle plate slants with a tapered angle with respect to the bottom of the hollow cylindrical member or the plurality of baffle plates arranged in the multiple stage manner. Thus, since each sub baffle plates slant with respect to the plurality of baffle plates arranged in the multiple stage manner, the captured particle is prevented from going out from the vortex of the gas flow. Thus, a capture rate of the particle increases.

Alternatively, each sub baffle plate further includes a canopy portion. Each canopy portion surrounds the opening disposed in the corresponding sub baffle plate, and extends toward a down stream side in the flowing passage of the raw material gas. When the sub baffle plates include the plurality of canopy portions, the canopy portions functions as a reverse portion so that the vortex of the raw material gas is prevented from being returned to a main stream of the raw material gas, which flows through the opening. Accordingly, the capture rate of the particle much increases.

Alternatively, each sub baffle plate has a cylindrical shape around the center axis of the hollow cylindrical member. A length of each sub baffle plate in a center axis direction of the hollow cylindrical member is shorter than a distance between two adjacent baffle plates arranged in the multiple stage manner and a distance between the bottom of the hollow cylindrical member and the utmost under baffle plate, the sub baffle plate being arranged between the two adjacent baffle plates. In the above case, the raw material gas passes through a clearance between each sub baffle plate and the corresponding baffle plate or a clearance between the sub baffle plate and the bottom of the hollow cylindrical member. When the gas passes through the clearance, the vortex is generated on the down stream side of the flowing direction of the raw material gas from the sub baffle plate. Thus, the particle is captured at the vortex. Accordingly, even when the device has the above structure, the particle is prevented from being attached to the growing surface of the SiC single crystal, and therefore, the device manufactures the SiC single crystal with high quality.

Further, each sub baffle plate between two adjacent baffle plates arranged in the multiple stage manner includes a predetermined number of plates. Thus, since the predetermined number of plates in each sub baffle plate are arranged, the number of times of formation of the vortex increases. Thus, the particle is captured frequently.

Alternatively, each sub baffle plate slants with a tapered angle with respect to the plurality of baffle plates arranged in the multiple stage manner, or the bottom of the hollow cylindrical member. Thus, since each sub baffle plates slant with respect to the plurality of baffle plates arranged in the multiple stage manner, the captured particle is prevented from going out from the vortex of the gas flow. Thus, a capture rate of the particle increases.

Alternatively, two adjacent plates of each sub baffle plate disposed between two adjacent baffle plates arranged in the multiple stage manner, and disposed between the bottom of the hollow cylindrical member and the utmost under baffle plate are alternately arranged to shift from each other in an up-down direction. Thus, the device has the structure such that two adjacent sub baffle plates are alternately arranged to shift from each other in the up-down direction. Thus, the flowing passage of the raw material gas is lengthened.

Further, the sub baffle plates includes an upper side sub baffle plate shifted to an upper side and a lower side sub baffle plate shifted to a lower side. The upper side sub baffle plate has a lower end, which is disposed on a down stream side of a flowing direction of the raw material gas from the upper end of the upper side sub baffle plate. The upper side sub baffle plate slants with a tapered angle with respect to the plurality of baffle plates arranged in the multiple stage manner or the bottom of the hollow cylindrical member. The lower side sub baffle plate has an upper end, which is disposed on the down stream side of the flowing direction of the raw material gas from a lower end of the lower side sub baffle plate. The lower side sub baffle plate slants with a tapered angle with respect to the plurality of baffle plates arranged in the multiple stage manner, or the bottom of the hollow cylindrical member. Thus, since each sub baffle plates slant with respect to the plurality of baffle plates arranged in the multiple stage manner, the captured particle is prevented from going out from the vortex of the gas flow. Thus, a capture rate of the particle increases.

Alternatively, each baffle plate is curved so as to have a convexity shape toward the raw material gas supply nozzle. Since the baffle plate have the above shape, the length of the flowing passage of the raw material gas is much elongated. Thus, the capture rate of the particle is much improved. Accordingly, a time interval, in which the raw material gas is exposed in high temperature circumstance in the heated heating chamber 9, is much lengthened.

Alternatively, a curvature of the convexity shape is in a range between 0.001 and 0.05.

According to a second aspect of the present disclosure, a manufacturing device of a silicon carbide single crystal includes: a reaction chamber; a seed crystal made of a silicon carbide single crystal substrate and arranged in the reaction chamber; and a heating chamber for heating a raw material gas. The seed crystal is disposed on an upper side of the reaction chamber. The raw material gas is supplied from an under side of the reaction chamber so that the gas reaches the seed crystal, and the silicon carbide single crystal is grown on the seed crystal. The heating chamber is disposed on an upstream side of a flowing passage of the raw material gas from the reaction chamber. The heating chamber includes a hollow cylindrical member, a raw material gas inlet, a raw material gas supply nozzle and a spiral passage portion. The raw material gas inlet introduces the raw material gas into the hollow cylindrical member. The raw material gas supply nozzle discharges the raw material gas from the hollow cylindrical member to the reaction chamber. The spiral passage portion provides a spiral flowing passage of the raw material gas between the raw material gas inlet and the raw material gas supply nozzle.

Thus, since the spiral passage portion is formed in the heating chamber so that the spiral shaped flowing passage is provided, the flowing passage of the raw material gas is elongated. In this case, a time interval, in which the raw material gas is exposed in high temperature circumstance in the heated heating chamber, is much lengthened. Thus, the device manufactures the SiC single crystal with high quality.

Alternatively, the heating chamber has an average flowing passage length of the raw material gas, which is defined as f. The average flowing passage length is an average length of the flowing passage of the raw material gas in the heating chamber. The average flowing passage length and a direct distance between the raw material gas inlet and the raw material gas supply nozzle defined as H has a relationship of f>1.2H.

Alternatively, the spiral passage portion includes a column shaft and a slant plate. The column shaft is arranged concentrically around a center axis of the hollow cylindrical member. The slant plate extends from the column shaft to an inner wall of the hollow cylindrical member. The slant plate is winded in a spiral manner around a center of the column shaft.

Alternatively, the manufacturing device further includes: a sub baffle plate. The sub baffle plate is disposed between an upper portion and a lower portion of the slant plate winded in a spiral manner. The sub baffle plate extends from the column shaft in a radial direction of the center axis of the hollow cylindrical member. The sub baffle plate intersects with the slant plate. The spiral passage portion further includes a sub baffle plate, which intersects with the slant plate. Thus, a vortex is generated in the gas flow on the down stream side of the flowing direction of the raw material gas with respect to each sub baffle plate. The particle is captured by the vortex. Thus, the particle is accumulated at a under portion on the down stream side of the flowing direction. Thus, the time interval, in which the raw material gas is exposed in high temperature circumstance, is much lengthened. Accordingly, the particle is effectively decomposed and disappeared. Further, the decomposed particle may be merged into the raw material gas again so that the particle provides growing material. Even if the particle is persistent, the particle is continuously captured in the vortex. Thus, the particle is prevented from being attached to the growing surface of the SiC single crystal, and therefore, the device manufactures the SiC single crystal with high quality.

Alternatively, the sub baffle plate connects between the upper portion and the lower portion of the slant plate, between which the sub baffle plate is arranged. The sub baffle plate has an opening for providing the flowing passage of the raw material gas. In the above case, the raw material gas flows through multiple openings. At this time, when the raw material gas passes through the sub baffle plate, the flowing passage is narrowed so that the flowing speed increases. Thus, the particle easily collides on the sub baffle plate.

Alternatively, the spiral passage portion further includes one or more sub baffle plates. Arrangement positions of the openings of multiple sub baffle plates are same. Alternatively, the spiral passage portion further includes one or more sub baffle plates, and arrangement positions of the openings of two adjacent sub baffle plates are different from each other. In the above cases, the number of the inner walls, on which the particle collides, increases. Further, the flowing passage length of the raw material gas is lengthened. Thus, the particle is frequently captured.

Alternatively, the spiral passage portion further includes a canopy portion. The canopy portion surrounds the opening of the corresponding sub baffle plate. The canopy portion extends toward a down stream side of a flowing direction of the raw material gas. When the spiral passage portion further includes a plurality of canopy portions, the canopy portions functions as a reverse portion so that the vortex of the raw material gas is prevented from being returned to a main stream of the raw material gas, which flows through the opening. Accordingly, the capture rate of the particle much increases.

Alternatively, a length of the sub baffle plate in a center axis direction of the hollow cylindrical member is shorter than a distance between the upper portion and the lower portion of the slant plate, between which the sub baffle plate is arranged. In the above structure, the raw material gas the raw material gas passes through a clearance between each sub baffle plate and the corresponding slant plate. When the gas passes through the clearance, the vortex is generated on the down stream side of the flowing direction of the raw material gas from the sub baffle plate. Thus, the particle is captured at the vortex. Accordingly, even when the device has the above structure, the time interval, in which the raw material gas is exposed in high temperature circumstance, is much lengthened. Accordingly, the particle is effectively decomposed and disappeared. Further, the decomposed particle may be merged into the raw material gas again so that the particle provides growing material. Even if the particle is persistent, the particle is continuously captured in the vortex. Thus, the particle is prevented from being attached to the growing surface of the SiC single crystal, and therefore, the device manufactures the SiC single crystal with high quality.

Alternatively, the sub baffle plate slants with a tapered angle with respect to the slant plate. Thus, since each sub baffle plates slants with respect to the slant plate, the captured particle is prevented from going out from the vortex of the gas flow. Thus, a capture rate of the particle increases.

Alternatively, two adjacent sub baffle plates between the upper portion and the lower portion of the slant plate are alternately arranged to shift from each other in an up-down direction. Thus, since two adjacent sub baffle plates are alternately arranged to shift from each other in an up-down direction, the flowing passage of the raw material gas is lengthened.

Alternatively, the sub baffle plate includes an upper side sub baffle plate shifted to an upper side and a lower side sub baffle plate shifted to a lower side. The upper side sub baffle plate has a lower end, which is disposed on a down stream side of a flowing direction of the raw material gas from the upper end of the upper side sub baffle plate. The upper side sub baffle plate slants with a tapered angle with respect to the plurality of baffle plates arranged in the multiple stage manner or the bottom of the hollow cylindrical member. The lower side sub baffle, plate has an upper end, which is disposed on the down stream side of the flowing direction of the raw material gas from a lower end of the lower side sub baffle plate. The lower side sub baffle plate slants with a tapered angle with respect to the plurality of baffle plates arranged in the multiple stage manner, or the bottom of the hollow cylindrical member. Thus, since each sub baffle plates slants with respect to the slant plate, the captured particle is prevented from going out from the vortex of the gas flow. Thus, a capture rate of the particle increases.

Alternatively, the heating chamber further includes a rectifier system. The rectifier system is disposed between the spiral passage portion and the raw material gas supply nozzle. The rectifier system aligns gas flow of the raw material gas, which is flown through the spiral passage portion, in a direction toward the raw material gas supply nozzle. Thus, since the device includes the rectifier system, the gas flow of the raw material gas flown through the spiral passage portion is rectified in a direction toward the raw material gas supply nozzle. Accordingly, since the rectified raw material gas without the vortex is supplied to the growing surface of the SiC single crystal, the SiC single crystal with high quality is grown.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A manufacturing device of a silicon carbide single crystal comprising:
a reaction chamber;
a seed crystal made of a silicon carbide single crystal substrate and arranged in the reaction chamber; and
a heating chamber for heating a raw material gas,
wherein the seed crystal is disposed on an upper side of the reaction chamber,
wherein the raw material gas is supplied from an under side of the reaction chamber so that the gas reaches the seed crystal, and the silicon carbide single crystal is grown on the seed crystal,
wherein the heating chamber is disposed on an upstream side of a flowing passage of the raw material gas from the reaction chamber,
wherein the heating chamber includes a hollow cylindrical member, a raw material gas inlet, a raw material gas supply nozzle and a plurality of baffle plates,
wherein the raw material gas inlet introduces the raw material gas into the hollow cylindrical member,
wherein the raw material gas supply nozzle discharges the raw material gas from the hollow cylindrical member to the reaction chamber, and
wherein the plurality of baffle plates are arranged on the flowing passage of the raw material gas between the raw material gas inlet and the raw material gas supply nozzle.

2. The manufacturing device of the silicon carbide single crystal according to claim 1,
wherein the heating chamber has an average flowing passage length of the raw material gas, which is defined as f,
wherein the average flowing passage length is an average length of the flowing passage of the raw material gas in the heating chamber, and
wherein the average flowing passage length and a direct distance between the raw material gas inlet and the raw material gas supply nozzle defined as H has a relationship of f>1.2H.

3. The manufacturing device of the silicon carbide single crystal according to claim 1,
wherein the plurality of baffle plates intersect with a center axis of the hollow cylindrical member and are arranged in a multiple stage manner along with the center axis as an arrangement direction,
wherein the plurality of baffle plates includes an utmost under baffle plate disposed nearest the raw material gas inlet, and
wherein the utmost under baffle plate covers the raw material gas inlet seeing from an upper side of the heating chamber.

4. The manufacturing device of the silicon carbide single crystal according to claim 3,
wherein the plurality of baffle plates includes an utmost upper baffle plate disposed nearest the raw material gas supply nozzle, and
wherein the utmost upper baffle plate covers the raw material gas supply nozzle seeing from a under side of the heating chamber.

5. The manufacturing device of the silicon carbide single crystal according to claim 4,
wherein the plurality of baffle plates includes a plurality of middle baffle plates disposed between the utmost under baffle plate and the utmost upper baffle plate,
wherein the middle baffle plates includes a middle baffle plate having a circular shape and another middle baffle plate having a ring shape,
wherein the middle baffle plate having the circular shape is adjacent to the utmost under baffle plate,
wherein the other middle baffle plate having the ring shape is adjacent to the middle baffle plate having the circular shape,
wherein the other middle baffle plate having the ring shape includes an opening,
wherein the middle baffle plate having the circular shape and the other middle baffle plate having the ring shape are repeatedly and alternately arranged, and
a radius of the middle baffle plate having the circular shape is larger than a radius of the opening of the other middle baffle plate having the ring shape, which is disposed under the middle baffle plate having the circular shape.

6. The manufacturing device of the silicon carbide single crystal according to claim 3,
a distance between two adjacent baffle plates disposed on the upper side is equal to or larger than a distance between two adjacent baffle plates disposed on the under side.

7. The manufacturing device of the silicon carbide single crystal according to claim 3, further comprising:
a plurality of sub baffle plates,
wherein the plurality of sub baffle plates are disposed between two adjacent baffle plates arranged in the multiple stage manner, and disposed between a bottom of the hollow cylindrical member and the utmost under baffle plate,
wherein each sub baffle plate intersects with the baffle plates arranged in the multiple stage manner, and
wherein each sub baffle plate extends in a direction intersecting with a radial direction with respect to the center axis of the hollow cylindrical member.

8. The manufacturing device of the silicon carbide single crystal according to claim 7,
wherein each sub baffle plate has a cylindrical shape around center axis of the hollow cylindrical member,
wherein each sub baffle plate connects between two adjacent baffle plates arranged in the multiple stage manner, and between the bottom of the hollow cylindrical member and the utmost under baffle plate, and
wherein each sub baffle plate has an opening for providing the flowing passage of the raw material gas.

9. The manufacturing device of the silicon carbide single crystal according to claim 8,
wherein each sub baffle plate disposed between two adjacent baffle plates arranged in the multiple stage manner, and disposed between the bottom of the hollow cylindrical member and the utmost under baffle plate includes a predetermined number of plates.

10. The manufacturing device of the silicon carbide single crystal according to claim 9,
wherein the openings of the predetermined number of plates of each sub baffle plate are arranged side-by-side in the radial direction with respect to the center axis of the hollow cylindrical member.

11. The manufacturing device of the silicon carbide single crystal according to claim 9,
wherein the openings of two adjacent plates of each sub baffle plate are arranged to shift from each other in a circumferential direction around the center axis of the hollow cylindrical member.

12. The manufacturing device of the silicon carbide single crystal according to claim 8,
wherein each sub baffle plate slants with a tapered angle with respect to the bottom of the hollow cylindrical member or the plurality of baffle plates arranged in the multiple stage manner.

13. The manufacturing device of the silicon carbide single crystal according to claim 8,
wherein each sub baffle plate further include a canopy portion, and
wherein each canopy portion surrounds the opening disposed in the corresponding sub baffle plate, and extends toward a down stream side in the flowing passage of the raw material gas.

14. The manufacturing device of the silicon carbide single crystal according to claim 7,
wherein each sub baffle plate has a cylindrical shape around the center axis of the hollow cylindrical member, and
wherein a length of each sub baffle plate in a center axis direction of the hollow cylindrical member is shorter than a distance between two adjacent baffle plates arranged in the multiple stage manner and a distance between the bottom of the hollow cylindrical member and the utmost under baffle plate, the sub baffle plate being arranged between the two adjacent baffle plates.

15. The manufacturing device of the silicon carbide single crystal according to claim 14,
wherein each sub baffle plate between two adjacent baffle plates arranged in the multiple stage manner includes a predetermined number of plates.

16. The manufacturing device of the silicon carbide single crystal according to claim 14,
wherein each sub baffle plate slants with a tapered angle with respect to the plurality of baffle plates arranged in the multiple stage manner, or the bottom of the hollow cylindrical member.

17. The manufacturing device of the silicon carbide single crystal according to claim 15,
wherein two adjacent plates of each sub baffle plate disposed between two adjacent baffle plates arranged in the multiple stage manner, and disposed between the bottom of the hollow cylindrical member and the utmost under baffle plate are alternately arranged to shift from each other in an up-down direction.

18. The manufacturing device of the silicon carbide single crystal according to claim 17,
wherein the sub baffle plates includes an upper side sub baffle plate shifted to an upper side and a lower side sub baffle plate shifted to a lower side,
wherein the upper side sub baffle plate has a lower end, which is disposed on a down stream side of a flowing direction of the raw material gas from the upper end of the upper side sub baffle plate,
wherein the upper side sub baffle plate slants with a tapered angle with respect to the plurality of baffle plates arranged in the multiple stage manner or the bottom of the hollow cylindrical member,
wherein the lower side sub baffle plate has an upper end, which is disposed on the down stream side of the flowing direction of the raw material gas from a lower end of the lower side sub baffle plate, and
wherein the lower side sub baffle plate slants with a tapered angle with respect to the plurality of baffle plates arranged in the multiple stage manner, or the bottom of the hollow cylindrical member.

19. The manufacturing device of the silicon carbide single crystal according to claim 3,
wherein each baffle plate is curved so as to have a convexity shape toward the raw material gas supply nozzle.

20. The manufacturing device of the silicon carbide single crystal according to claim 19,
wherein a curvature of the convexity shape is in a range between 0.001 and 0.05.

21. A manufacturing device of a silicon carbide single crystal comprising:
a reaction chamber;
a seed crystal made of a silicon carbide single crystal substrate and arranged in the reaction chamber; and
a heating chamber for heating a raw material gas,
wherein the seed crystal is disposed on an upper side of the reaction chamber,
wherein the raw material gas is supplied from an under side of the reaction chamber so that the gas reaches the seed crystal, and the silicon carbide single crystal is grown on the seed crystal,
wherein the heating chamber is disposed on an upstream side of a flowing passage of the raw material gas from the reaction chamber,
wherein the heating chamber includes a hollow cylindrical member, a raw material gas inlet, a raw material gas supply nozzle and a spiral passage portion,
wherein the raw material gas inlet introduces the raw material gas into the hollow cylindrical member,
wherein the raw material gas supply nozzle discharges the raw material gas from the hollow cylindrical member to the reaction chamber, and
wherein the spiral passage portion provides a spiral flowing passage of the raw material gas between the raw material gas inlet and the raw material gas supply nozzle.

22. The manufacturing device of the silicon carbide single crystal according to claim 21,
wherein the heating chamber has an average flowing passage length of the raw material gas, which is defined as f,
wherein the average flowing passage length is an average length of the flowing passage of the raw material gas in the heating chamber, and
wherein the average flowing passage length and a direct distance between the raw material gas inlet and the raw material gas supply nozzle defined as H has a relationship of f>1.2H.

23. The manufacturing device of the silicon carbide single crystal according to claim 21,
wherein the spiral passage portion includes a column shaft and a slant plate,
wherein the column shaft is arranged concentrically around a center axis of the hollow cylindrical member,
wherein the slant plate extends from the column shaft to an inner wall of the hollow cylindrical member, and
wherein the slant plate is winded in a spiral manner around a center of the column shaft.

24. The manufacturing device of the silicon carbide single crystal according to claim 23, further comprising:
a sub baffle plate,
wherein the sub baffle plate is disposed between an upper portion and a lower portion of the slant plate winded in a spiral manner,
wherein the sub baffle plate extends from the column shaft in a radial direction of the center axis of the hollow cylindrical member, and
wherein the sub baffle plate intersects with the slant plate.

25. The manufacturing device of the silicon carbide single crystal according to claim 23,
wherein the sub baffle plate connects between the upper portion and the lower portion of the slant plate, between which the sub baffle plate is arranged; and
wherein the sub baffle plate has an opening for providing the flowing passage of the raw material gas.

26. The manufacturing device of the silicon carbide single crystal according to claim 25,
wherein the spiral passage portion further includes one or more sub baffle plates; and
wherein arrangement positions of, the openings of multiple sub baffle plates are same.

27. The manufacturing device of the silicon carbide single crystal according to claim 25,
wherein the spiral passage portion further includes one or more sub baffle plates; and
wherein arrangement positions of the openings of two adjacent sub baffle plates are different from each other.

28. The manufacturing device of the silicon carbide single crystal according to claim 24,
wherein the spiral passage portion further includes a canopy portion,
wherein the canopy portion surrounds the opening of the corresponding sub baffle plate, and
wherein the canopy portion extends toward a down stream side of a flowing direction of the raw material gas.

29. The manufacturing device of the silicon carbide single crystal according to claim 24,
wherein a length of the sub baffle plate in a center axis direction of the hollow cylindrical member is shorter than a distance between the upper portion and the lower portion of the slant plate, between which the sub baffle plate is arranged.

30. The manufacturing device of the silicon carbide single crystal according to claim 29,
wherein the sub baffle plate slants with a tapered angle with respect to the slant plate.

31. The manufacturing device of the silicon carbide single crystal according to claim 29,
two adjacent sub baffle plates between the upper portion and the lower portion of the slant plate are alternately arranged to shift from each other in an up-down direction.

32. The manufacturing device of the silicon carbide single crystal according to claim 31,
wherein the sub baffle plate includes an upper side sub baffle plate shifted to an upper side and a lower side sub baffle plate shifted to a lower side,
wherein the upper side sub baffle plate has a lower end, which is disposed on a down stream side of a flowing direction of the raw material gas from the upper end of the upper side sub baffle plate,
wherein the upper side sub baffle plate slants with a tapered angle with respect to the plurality of baffle plates arranged in the multiple stage manner or the bottom of the hollow cylindrical member,
wherein the lower side sub baffle plate has an upper end, which is disposed on the down stream side of the flowing direction of the raw material gas from a lower end of the lower side sub baffle plate, and
wherein the lower side sub baffle plate slants with a tapered angle with respect to the plurality of baffle plates arranged in the multiple stage manner, or the bottom of the hollow cylindrical member.

33. The manufacturing device of the silicon carbide single crystal according to claim 21,
wherein the heating chamber further includes a rectifier system,
wherein the rectifier system is disposed between the spiral passage portion and the raw material gas supply nozzle, and
wherein the rectifier system aligns gas flow of the raw material gas, which is flown through the spiral passage portion, in a direction toward the raw material gas supply nozzle.
